(19) United States
(12) Patent Application Publication
(10) Pub. No.: US 2025/0098405 A1
(43) Pub. Date: Mar. 20, 2025

(54) LIGHT EMITTING DEVICE AND DISPLAY PANEL

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Juncong LI, Beijing (CN); Rongrong GAO, Beijing (CN); Xianwen MENG, Beijing (CN)

(21) Appl. No.: 18/290,032

(22) PCT Filed: Feb. 24, 2023
(86) PCT No.: PCT/CN2023/078073

§ 371 Date: Nov. 9, 2023

(51) Int. Cl. H10K 50/852; C09K 11/06; H10K 50/16; H10K 50/858

(52) U.S. Cl. CPC H10K 50/852; C09K 11/06; H10K 50/16; H10K 50/858; C09K 2211/1007; C09K 2211/1011; C09K 2211/1014; C09K 2211/1018

(57) ABSTRACT

The present disclosure provides a light emitting device and a display panel, and belongs to the field of display technology. The light emitting device includes a first electrode, a second electrode and a light emitting functional layer arranged between the first electrode and the second electrode; the light emitting functional layer at least includes an electron transport layer and a hole blocking layer; the electron transport layer has a refractive index between 1.6 and 1.9, and an optical thickness in a range from 540 Å to 700 Å; and a difference between the refractive index of the electron transport layer and a refractive index of the hole blocking layer is less than or equal to 0.1.

### TECHNICAL FIELD

The present disclosure relates to the field of display technology, in particular to a light emitting device and display panel.

### BACKGROUND

An organic light emitting diode (OLED) is a light emitting device with an organic solid semiconductor as a light emitting material, and has the advantages of simple manufacturing process, low cost, low power consumption, high luminance, wide operating temperature application range, and the like, and thus has a wide application prospect. In recent years, an OLED display has been receiving more attention as a new display product.

With the continuous development of OLED technology, an OLED device is gradually developed into a thin film device including a multilayer structure having functional layers. People pay more attention to research on efficient organic materials and device performances of the OLED device, and the OLED device generally has a high efficiency and a long service life through an optimized combination of various organic materials, which provides great opportunities and challenges for designing and developing functional materials for various structures and structures of devices.

### SUMMARY

The present disclosure is directed to solving at least one of the technical problems in the related art, and provides a light emitting device and a display panel.

In a first aspect, the technical solution adopted for solving the technical problems in the related art is a light emitting device, including a first electrode, a second electrode, and a light emitting functional layer between the first electrode and the second electrode; wherein the light emitting functional layer at least includes an electron transport layer and a hole blocking layer; the electron transport layer has a refractive index between 1.6 and 1.9, and an optical thickness in a range from 540 Å to 700 Å; and a difference between the refractive index of the electron transport layer and a refractive index of the hole blocking layer is less than or equal to 0.1.

In some implementations, the light emitting device is a blue light emitting device, and the electron transport layer has the refractive index between 1.7 and 1.9, and the optical thickness between 600 Å and 700 Å.

In some implementations, the light emitting device is a green light emitting device, the electron transport layer has the refractive index between 1.65 and 1.85, and the optical thickness between 570 Å and 670 Å.

In some implementations, the light emitting device is a red light emitting device, the electron transport layer has the refractive index between 1.6 and 1.8, and the optical thickness between 540 Å and 640 Å.

In some implementations, a material of the electron transport layer includes any one of: a benzimidazole derivative, an imidazopyridine derivative, a benzimidazophenanthridine derivative, a pyrimidine derivative, a triazine derivative, a quinoline derivative, an isoqu.inoline derivative, and a phenanthroline derivative.

In some implementations, the light emitting device further includes a plurality of capping layers stacked on a side of the second electrode away from the first electrode; where, at least part of the plurality of capping layers is a first capping layer, the rest is a second capping layer, and a refractive index of the first capping layer is different from that of the second capping layer.

In some implementations, the refractive index of the first capping layer is greater than that of the second capping layer; and the first capping layer is closer to the second electrode than the second capping layer.

In some implementations, the refractive index of the first capping layer is between 1.95 and 2.31; the refractive index of the second capping layer is between 1.618 and 1.703.

In some implementations, the light emitting device is a blue light emitting device; and an optical thickness of the first capping layer is between 1300 Å and 1600 Å, and an optical thickness of the second capping layer is between 1100 Å and 1500 Å.

In some implementations, the light emitting device is a green light emitting device; an optical thickness of the first capping layer is between 1200 Å and 1500 Å, and an optical thickness of the second capping layer is between 1000 Å and 1400 Å.

In some implementations, the light emitting device is a red light emitting device; an optical thickness of the first capping layer is between 1100 Å and 1400 Å, and an optical thickness of the second capping layer is between 900 Å and 1300 Å.

In some implementations, the material of the first capping layer has the following general structural formula (I):

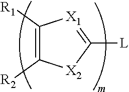

where, m is equal to 2; L represents any one of phenylene, biphenylene, naphthylene, a general structural formula (II), a general structural formula (III), a general structural formula (IV) and a general structural formula (V); X1 is N or CR, X2 is any one of S, O and NR, wherein R in CR, R in NR, R1 and R2 independently represent one of the following substances: hydrogen, deuterium, a substituted or unsubstituted alkyl group, a substituted or unsubstituted cycloalkyl group, a substituted or unsubstituted heterocyclic group, a substituted or unsubstituted alkenyl group, a substituted or unsubstituted cycloalkenyl group, a substituted or unsubstituted alkynyl group, a substituted or unsubstituted alkoxy group, a substituted or unsubstituted alkylthio group, a substituted or unsubstituted aryl ether group, a substituted or unsubstituted aryl thioether group, a substituted or unsubstituted C6 to C60 aryl group, a substituted or unsubstituted C6 to C60 heteroaryl group, a substituted or unsubstituted carbonyl group, a substituted or unsubstituted oxycarbonyl group, a substituted or unsubstituted carbamoyl group, a substituted or unsubstituted silane group, a substituted or unsubstituted alkylamine group, and a substituted or unsubstituted aryl amido group;
the general structural formula (II):

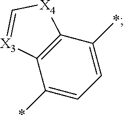

the general structural formula (III):

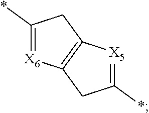

the general structural formula (IV):

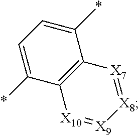

the general structural formula (V):

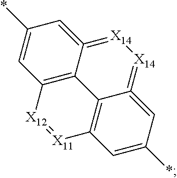

where X₃ represents N or CR; X₄ represents S, O or NR; X₅ and X₆ each independently represent S or O; X₇, X₈, X₉, X₁₀ all independently represent N or CR, and at least one of X₇, X₈, X₉, X₁₀ is N; X₁₁, X₁₂, X₁₃, X₁₄ all independently represent N or CR, and at least two of X₁₁, X₁₂, X₁₃, X₁₄ are N; * denotes the position to which the general structural formula (I) is connected.

In some implementations, the L includes any one of the following structures:

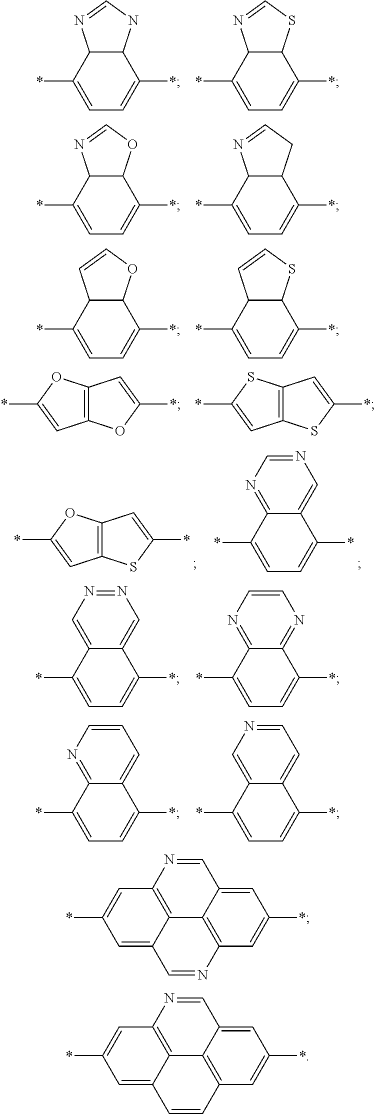

In some implementations, the structure of the material of the first capping layer includes any one of following structures:

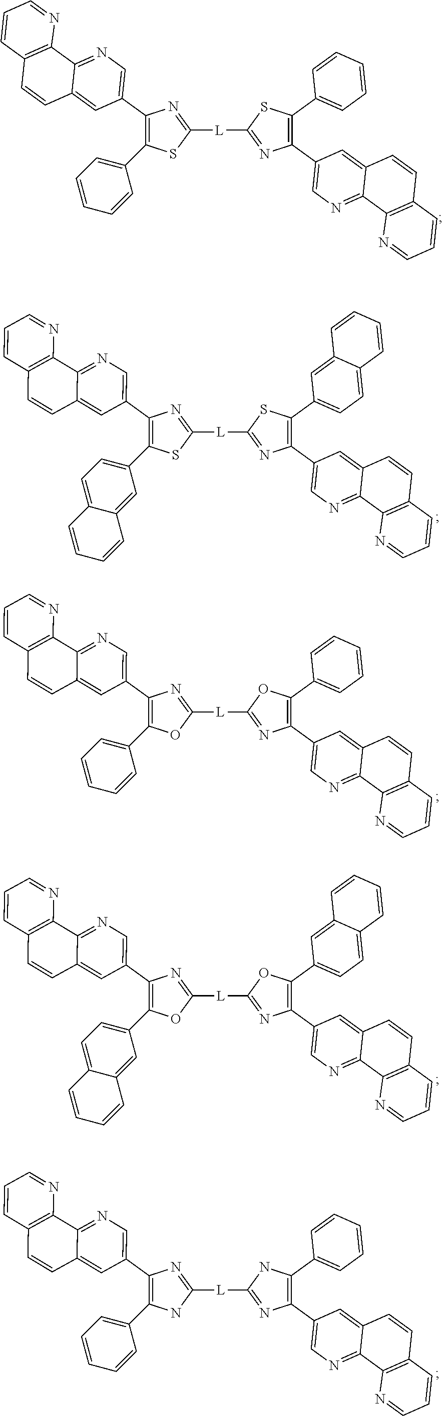

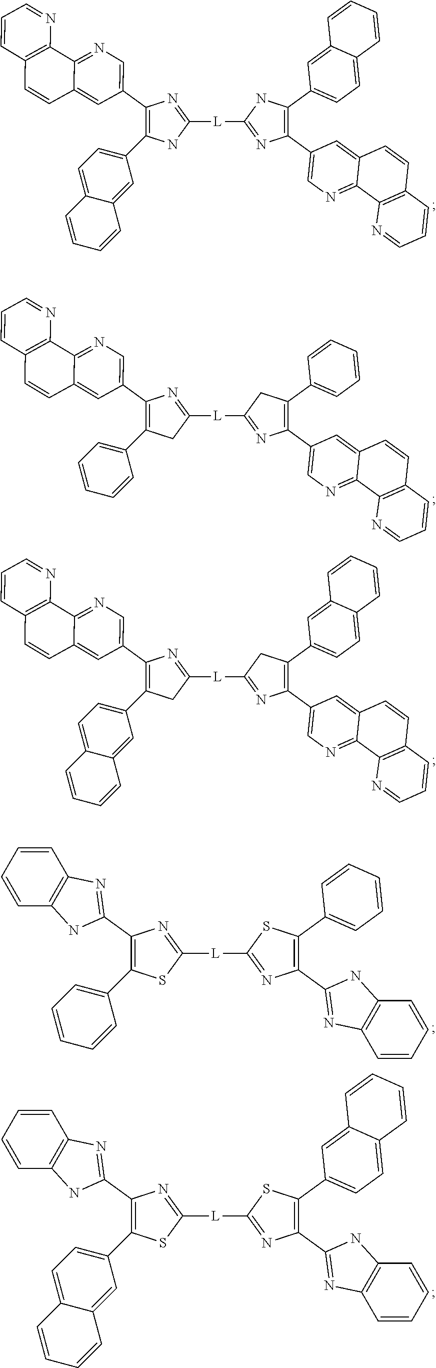

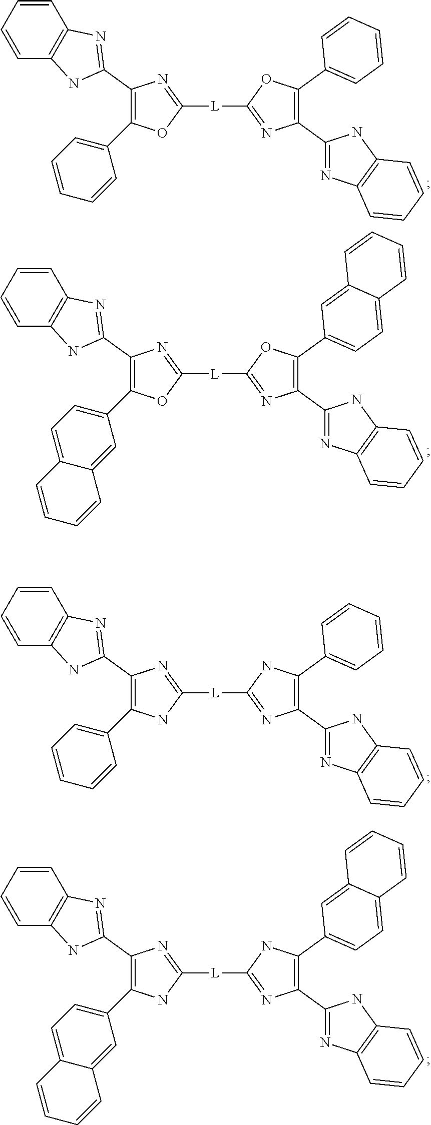

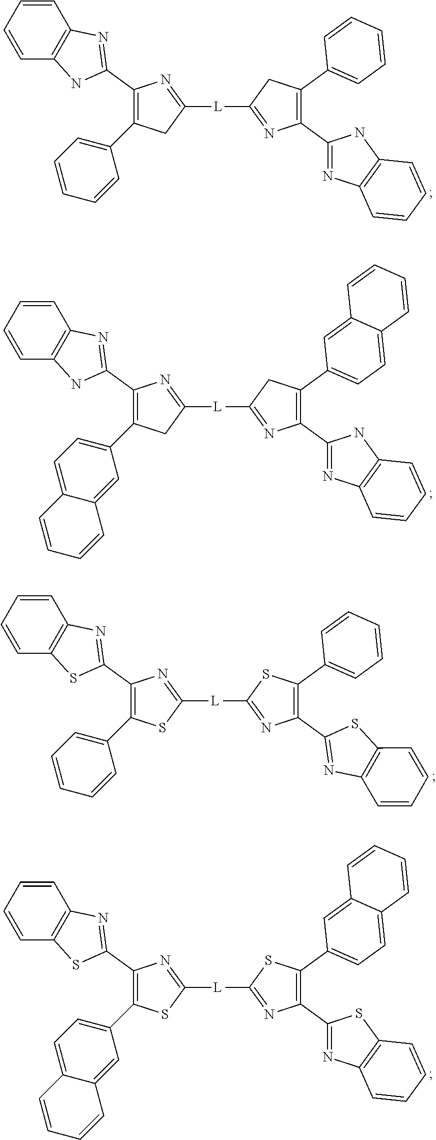

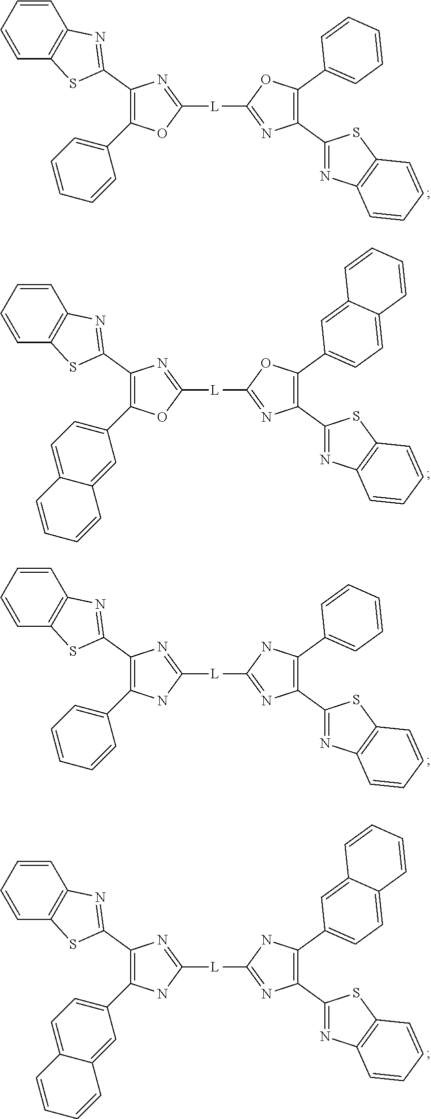

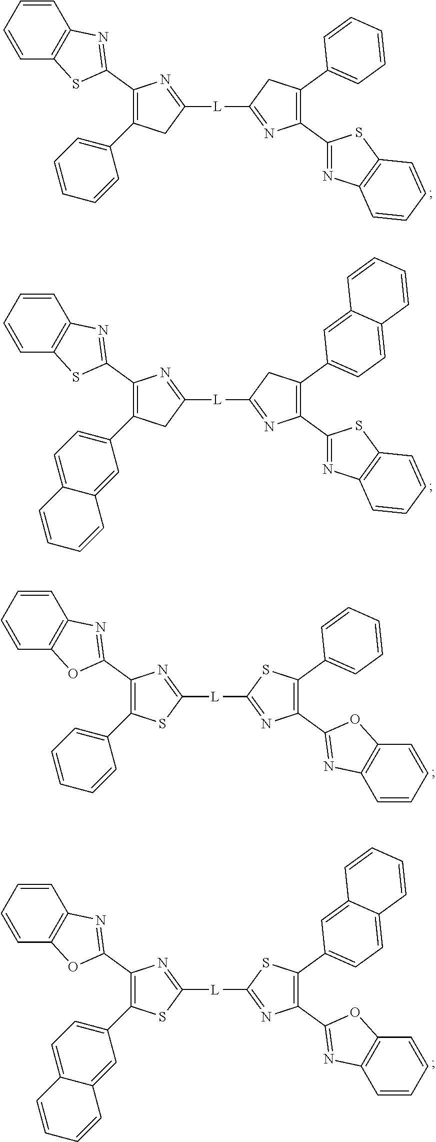

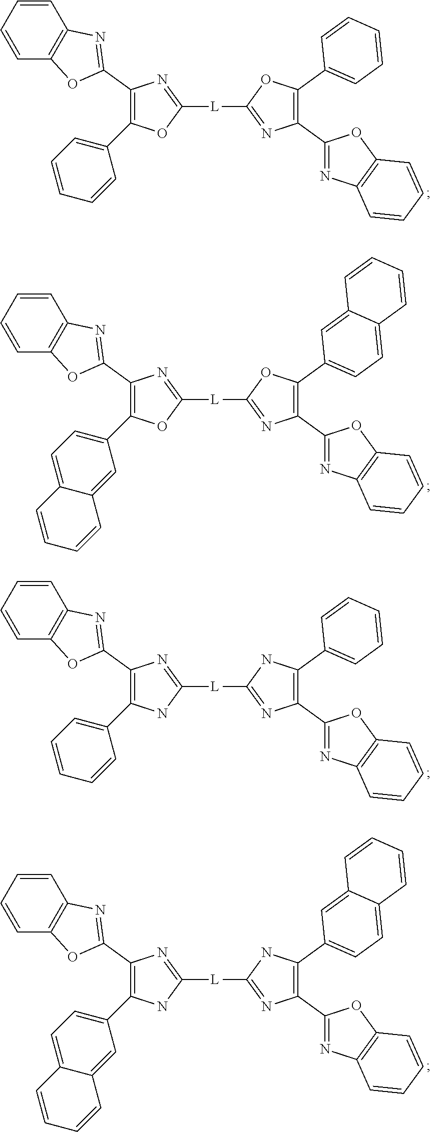

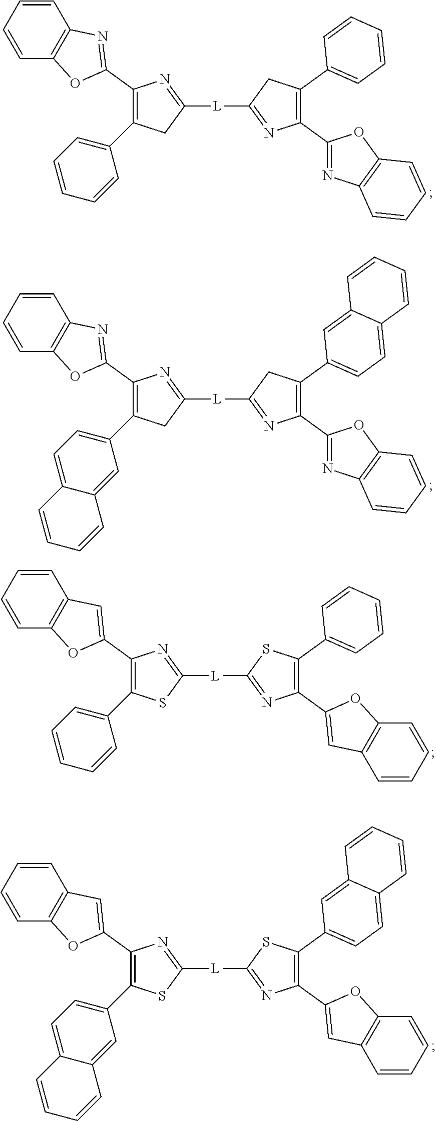

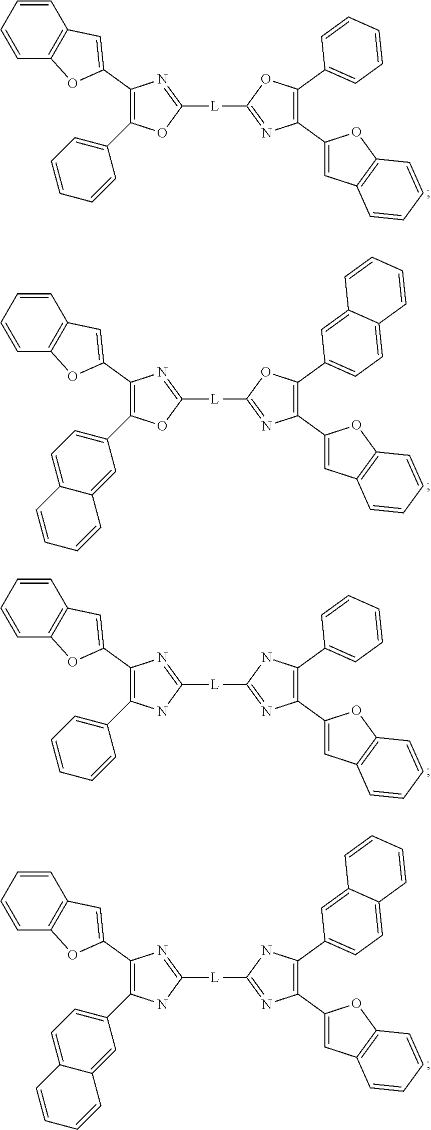

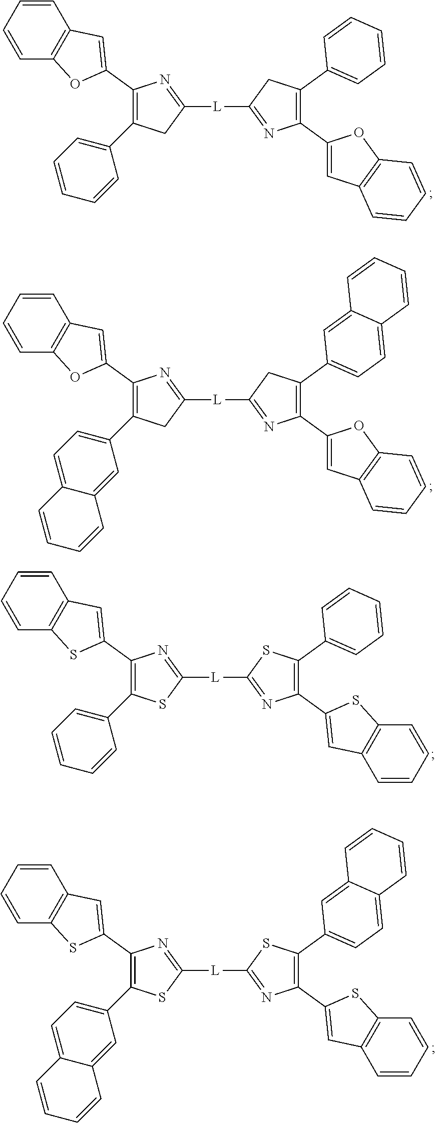

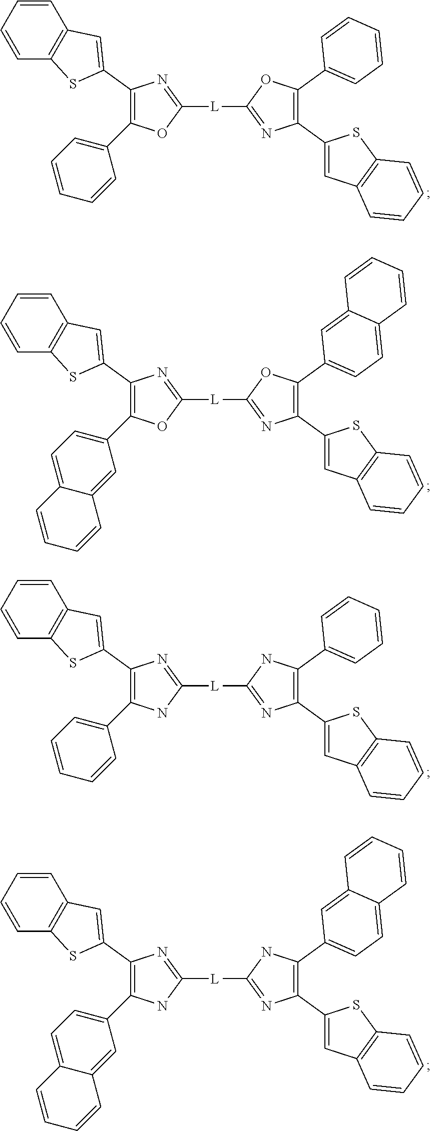

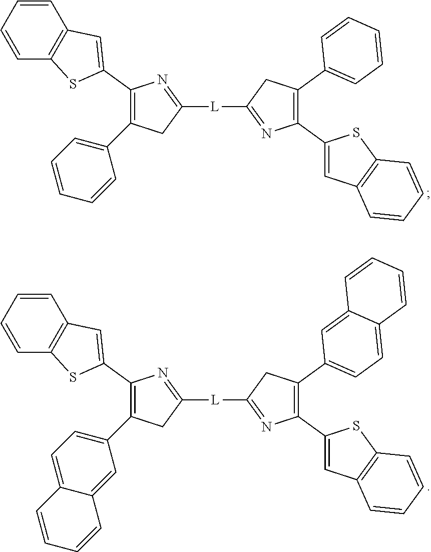

In some implementations, the material of the second capping layer has the following general structural formula (VI):
the general structural formula (VI):

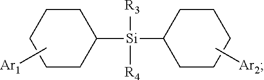

where, Ar₁ represents a general structural formula (VII) or (VIII), Ar₂ represents the general structural formula (VII) or (VIII);
   the general structural formula (VII):

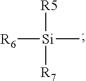

the general structural formula (VIII):

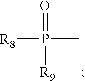

where, R₃, R₄, R₅, R₆, R₇, R₈, and R₉ each independently represent one of the following substances: a substituted or unsubstituted alkyl group, a substituted or unsubstituted cycloalkyl group, a substituted or unsubstituted heterocyclic group, a substituted or unsubstituted alkenyl group, a substituted or unsubstituted cycloalkenyl group, a substituted or unsubstituted alkynyl group, a substituted or unsubstituted alkoxy group, a substituted or unsubstituted alkylthio group, a substituted or unsubstituted aryl ether group, a substituted or unsubstituted aryl thioether group, a substituted or unsubstituted C6 to C60 aryl group, a substituted or unsubstituted C6 to C60 heteroaryl group, a substituted or unsubstituted carbonyl group, a substituted or unsubstituted oxycarbonyl group, a substituted or unsubstituted carbamoyl group, a substituted or unsubstituted silane group, a substituted or unsubstituted alkylamine group, and a substituted or unsubstituted aryl amido group.

In some implementations, a part of hydrogen in any one of the following structures independently represented by R₃, R₄, R₅, R₆, R₇, R₈, and R₉ is substituted by deuterium: a substituted or unsubstituted alkyl group, a substituted or unsubstituted cycloalkyl group, a substituted or unsubstituted heterocyclic group, a substituted or unsubstituted alkenyl group, a substituted or unsubstituted cycloalkenyl group, a substituted or unsubstituted alkynyl group, a substituted or unsubstituted alkoxy group, a substituted or unsubstituted alkylthio group, a substituted or unsubstituted aryl ether group, a substituted or unsubstituted aryl thioether group, a substituted or unsubstituted C6 to C60 aryl group, a substituted or unsubstituted C6 to C60 heteroaryl group, a substituted or unsubstituted carbonyl group, a substituted or unsubstituted oxycarbonyl group, a substituted or unsubstituted carbamoyl group, a substituted or unsubstituted silane group, a substituted or unsubstituted alkylamine group, and a substituted or unsubstituted aryl amido group.

In some implementations, the Ar₁ and the Ar₂ each include any one of the following structures:

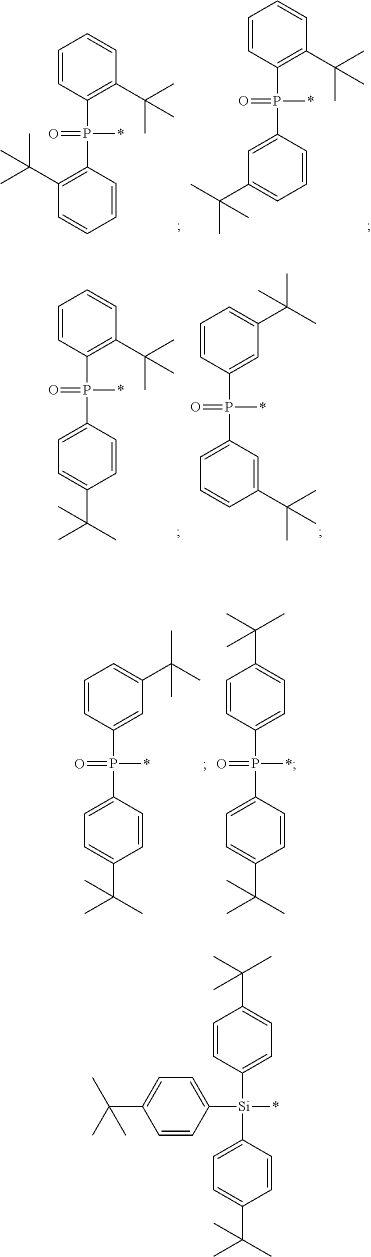

where, * denotes a position to which the general structural formula (VI) is connected.

In some implementations, the structure of the material of the second capping layer includes any one of the following structures:

[chemical structure]

In a second aspect, an embodiment of the present disclosure further provides a display panel, including the light emitting device according to any one of the above embodiments.

### BRIEF DESCRIPTION OF DRAWINGS

FIG. 1 is a schematic diagram of a structure of a light emitting device according to an embodiment of the present disclosure;

FIG. 2 is a schematic diagram of a structure of an exemplary light emitting device according to an embodiment of the present disclosure.

Reference numbers are: 1. a first electrode; 2. a second electrode; 3. a light emitting functional layer; HIL, a hole injection layer; HTL, a hole transport layer; EBL, an electron blocking layer; R-EBL, an electron blocking layer in a red light emitting device; G-EBL, an electron blocking layer in a green light emitting device; B-EBL, an electron blocking layer in a blue light emitting device; EML, a light emitting layer; R-EML, a red light emitting layer; G-EML, a green light emitting layer; B-EML, a blue light emitting layer; HBL, a hole blocking layer; ETL, an electron transport layer; EIL, an electron injection layer; CPL1, a first capping layer; CPL2, a second capping layer; 01. a blue light emitting device; 02. a green light emitting device; 03. a red light emitting device.

### DETAIL DESCRIPTION OF EMBODIMENTS

To make the objects, technical solutions and advantages of the embodiments of the present disclosure more apparent, the technical solutions of the embodiments of the present disclosure will be clearly and completely described below with reference to the drawings of the embodiments of the present disclosure. It is to be understood that the described embodiments are only a few, not all of, embodiments of the present disclosure. Components of the embodiments of the present disclosure, as generally described and illustrated in the drawings herein, could be arranged and designed in a wide variety of different configurations. Thus, the following detailed description of the embodiments of the present disclosure in the drawings is not intended to limit the protective scope of the present disclosure, but is merely representative of selected embodiments of the present disclosure. All other embodiments, which can be derived by a person skilled in the art from the embodiments of the present disclosure without any increative effort, are within the protective scope of the present disclosure.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term of “comprising/comprise”, “including/include”, or the like, means that the element or item preceding the term contains the element or item listed after the term and its equivalent, but does not exclude other elements or items. The term “connected/connecting”, “coupled/coupling”, or the like is not limited to physical or mechanical connections, but may include electrical connections, whether direct or indirect connections. The terms “upper/on”, “lower/under”, “left”, “right”, and the like are used only for indicating relative positional relationships, and when the absolute position of an object being described is changed, the relative positional relationships may also be changed accordingly.

It should be noted that a light emitting principle of a light emitting device is as follows: holes are injected through an anode and electrons are injected through a cathode, and the holes and the electrons pass through light emitting functional layer and are recombined in a light emitting layer to form excitons, which are subjected to radiation transition to emit photons. Therefore, a position of a recombination region where the holes and the electrons are combined in the light emitting layer is important. At present, in a certain OLED device in the related art, the recombination region where the holes and the electrons are recombined is narrow and is closer to an electron blocking layer. If excitons are formed in layers other than the light emitting layer through a recombination, the light emitting efficiency is seriously reduced, and a transport layer adjacent to the light emitting layer emits light, so that the color purity of the device is low.

It should be noted that a thickness and a refractive index of a film layer in the light emitting device affect the light emitting efficiency of specific light. The inventors have found through research that a material of an electron transport layer with a low refractive index can more advantageously ensure a gain for a light emitting wavelength under a microcavity effect of the light emitting device than that of other functional sub-layer with a low refractive index in the light emitting functional layer. Based on this, an embodiment of the present disclosure provides a light emitting device, including a first electrode, a second electrode, and a light emitting functional layer disposed between the first electrode and the second electrode; the light emitting functional layer at least includes an electron transport layer and a hole blocking layer; the electron transport layer has a refractive index between 1.6 and 1.9, and an optical thickness in a range from 540 Å to 700 Å; a difference between the refractive index of the electron transport layer and a refractive index of the hole blocking layer is less than or equal to 0.1.

The electron transport layer of the light emitting device provided by the embodiment of the present disclosure has the low refractive index between 1.6 and 1.9, which can ensure the gain for the light emitting wavelength under the microcavity effect of the light emitting device. The optical thickness of the electron transport layer is selected to be in a range from 540 Å to 700 Å, which further improves the gain for the light emitting wavelength under the microcavity effect of the light emitting device. In addition, in the present disclosure, only one layer is adjusted, that is, only the refractive index and the optical thickness of one electron transport layer in the light emitting functional layer are adjusted, so that the gain for the light emitting wavelength under the microcavity effect of the light emitting device is realized, and the manufacturing difficulty and the process cost for the light emitting device can be reduced. In addition, the difference between the refractive index of the electron transport layer and the refractive index of the hole blocking layer is less than or equal to 0.1, so that total reflection of light in a resonant microcavity can be avoided, and the light extraction efficiency is improved.

It should be noted that the microcavity effect is: a light emitting region of the light emitting device is located in a resonant cavity formed by a total reflection film and a semi-reflection film, and a cavity length of the light emitting device is in the same order of magnitude as the light emitting wavelength, so that the light with a specific wavelength can be selected and enhanced, and the spectrum is narrowed.

It should be noted that the optical thickness of the film layer in the present disclosure is a product of the refractive index and a thickness of the film layer, and the thickness of the film layer is an actual physical thickness of the film layer.

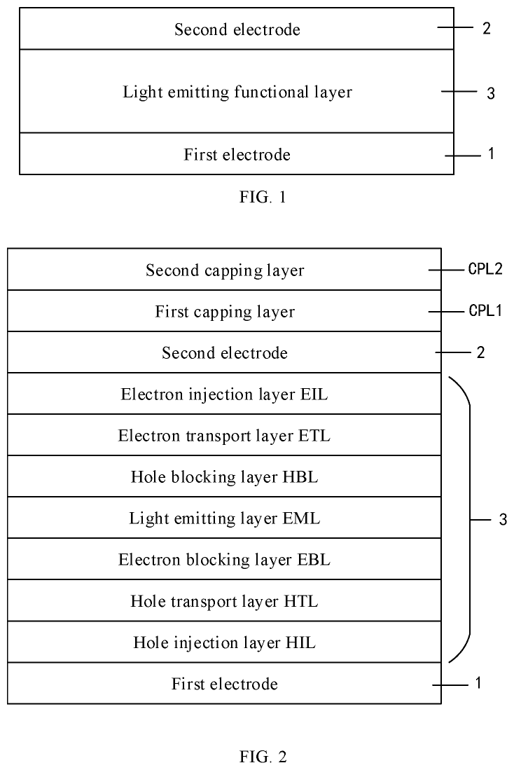

The light emitting device provided by an embodiment of the present disclosure will be described in detail below. FIG. 1 is a schematic diagram of a structure of a light emitting device according to an embodiment of the present disclosure; as shown in FIG. 1, the light emitting device includes a first electrode 1, a second electrode 2, and a light emitting functional layer 3 disposed between the first electrode 1 and the second electrode 2, where the light emitting functional layer 3 includes a light emitting layer EML and a functional sub-layer, and the functional sub-layer includes at least one layer. The functional sub-layer includes at least an electron transport layer ETL. The electron transport layer ETL has a refractive index between 1.6 and 1.9, and an optical thickness in a range from 540 Å to 700 Å. The electron transport layers ETL in light emitting devices of different colors have different refractive index ranges and different optical thicknesses.

The light emitting functional layer 3 includes a hole blocking layer HBL in addition to the electron transport layer ETL. As shown in FIG. 2, a difference between the refractive index of the electron transport layer ETL and a refractive index of the hole blocking layer HBL is less than or equal to 0.1. Here, the refractive index of the electron transport layer ETL and the refractive index of the hole blocking layer HBL are separately provided, or one of the refractive indexes is individually provided, so that the difference between the refractive indexes is small, thereby preventing the total reflection caused by the large difference between the refractive indexes of the adjacent layers from affecting the light extraction. That is, the difference between the refractive index of the electron transport layer ETL and the refractive index of the hole blocking layer HBL is less than or equal to 0.1, so that the total reflection of light in the resonant microcavity can be avoided, thereby improving the light extraction efficiency.

In some implementations, the light emitting device is a blue light emitting device 01, the refractive index of the electron transport layer ETL is between 1.7 and 1.9, and the optical thickness of the electron transport layer ETL is between 600 Å and 700 Å.

Here, the refractive index of the electron transport layer ETL in the blue light emitting device 01 is low and between 1.7 and 1.9, which can ensure the gain for the blue light wavelength under the microcavity effect of the blue light emitting device 01. The optical thickness of the electron transport layer ETL is selected to be in a range from 600 Å to 700 Å, which further improves the gain for the blue light wavelength under the microcavity effect of the blue light emitting device 01. In addition, only the refractive index and the optical thickness of one electron transport layer ETL in the light emitting functional layer 3 are adjusted, so that the gain for the light emitting wavelength under the microcavity effect of the blue light emitting device 01 is realized, and the manufacturing difficulty and the process cost for the blue light emitting device 01 can be reduced.

In some implementations, the light emitting device is the blue light emitting device 01, and a thickness of the electron transport layer ETL is between 31.58 nm and 41.18 nm. Here, the electron transport layer ETL with a low refractive index is used, and in order to ensure the balance of carriers, the thickness of the electron transport layer ETL is increased, thereby increasing a distance that the electron is transported, and achieving the purpose of adjusting a position of the recombination region where the electrons and the holes are recombined in the light emitting layer EML (specifically, the recombination region for excitons is enlarged and moved toward the electron transport layer ETL, and thus, the recombination region for excitons is away from an interface between the electron blocking layer EBL and the light emitting layer EML), and improving the exciton recombination efficiency and the efficiency and the lifetime of the blue light emitting device 01.

Illustratively, the blue light emitting device 01 in the embodiment of the present disclosure emits blue light with a wavelength in a range from 400 nm to 480 nm. For example, the wavelength of the blue light is 460 nm.

In some implementations, the light emitting device is a green light emitting device 02, the refractive index of the electron transport layer ETL is between 1.65 and 1.85, and the optical thickness of the electron transport layer ETL is between 570 Å and 670 Å.

Here, the refractive index of the electron transport layer ETL in the green light emitting device 02 is low and between 1.65 and 1.85, which can ensure the gain for the green light wavelength under the microcavity effect of the green light emitting device 02. The optical thickness of the electron transport layer ETL is selected to be in a range from 570 Å to 670 Å, which further improves the gain for the green light wavelength under the microcavity effect of the green light emitting device 02. In addition, only the refractive index and the optical thickness of one electron transport layer ETL in the light emitting functional layer 3 are adjusted, so that the gain for the green light wavelength under the microcavity effect of the green light emitting device 02 is realized, and the manufacturing difficulty and the process cost for the green light emitting device 02 can be reduced.

In some implementations, the light emitting device is the green light emitting device 02 and a thickness of the electron transport layer ETL is between 30.81 nm and 40.61 nm. Here, the electron transport layer ETL with a low refractive index is used, and in order to ensure the balance of carriers, the thickness of the electron transport layer ETL is increased, thereby increasing a distance that the electron is transported, and achieving the purpose of adjusting the position of the recombination region where the electrons and the holes are recombined in the light emitting layer EML (specifically, the recombination region for excitons is enlarged and moved toward the electron transport layer ETL, and thus, the recombination region for excitons is away from an interface between the electron blocking layer EBL and the light emitting layer EML), and improving the exciton recombination efficiency and the efficiency and the lifetime of the green light emitting device 02.

Illustratively, the green light emitting device 02 in the embodiment of the present disclosure emits green light with a wavelength in a range from 492 nm to 577 nm. For example, the wavelength of the green light is 530 nm.

In some implementations, the light emitting device is a red light emitting device 03, the refractive index of the electron transport layer ETL is between 1.6 and 1.8, and the optical thickness of the electron transport layer ETL is between 540 Å and 640 Å.

Here, the refractive index of the electron transport layer ETL in the red light emitting device 03 is low and between 1.6 and 1.8, which can ensure the gain for the red light wavelength under the microcavity effect of the red light emitting device 03. The optical thickness of the electron transport layer ETL is selected to be in a range from 540 Å to 640 Å, which further improves the gain for the red light wavelength under the microcavity effect of the red light emitting device 03. In addition, only the refractive index and the optical thickness of one electron transport layer ETL in the light emitting functional layer 3 are adjusted, so that the gain for the green light wavelength under the microcavity effect of the red light emitting device 03 is realized, and the manufacturing difficulty and the process cost for the red light emitting device 03 can be reduced.

In some implementations, the light emitting device is the red light emitting device 03 and a thickness of the electron transport layer ETL is between 30 nm and 40 nm. Here, the electron transport layer ETL with a low refractive index is used, and in order to ensure the balance of carriers, the thickness of the electron transport layer ETL is increased, thereby increasing a distance that the electron is transported, and achieving the purpose of adjusting the position of the recombination region where the electrons and the holes are recombined in the light emitting layer EML (specifically, the recombination region for excitons is enlarged and moved toward the electron transport layer ETL, and thus, the recombination region for excitons is away from an interface between the electron blocking layer EBL and the light emitting layer EML), and improving the exciton recombination efficiency and the efficiency and the lifetime of the red light emitting device 03.

Illustratively, the red light emitting device 03 in the embodiment of the present disclosure emits red light with a wavelength in a range from 600 nm to 760 nm. For example, the wavelength of the red light is 620 nm.

FIG. 2 is a schematic diagram of a structure of an exemplary light emitting device according to an embodiment of the present disclosure. As shown in FIG. 2, as an example, the first electrode 1 is an anode and the second electrode 2 is a cathode, the light emitting functional layer 3 includes one light emitting layer EML and a plurality of functional sub-layers; the plurality of functional sub-layers include a hole injection layer HIL arranged on a side of the first electrode 1 close to the light emitting layer EML, a hole transport layer HTL arranged on a side of the hole injection layer HIL close to the light emitting layer EML, an electron blocking layer EBL arranged on a side of the hole transport layer HTL close to the light emitting layer EML, a hole blocking layer HBL on a side of the light emitting layer EML away from the first electrode 1, an electron transport layer ETL on a side of the hole blocking layer HBL away from the light emitting layer EML, and an electron injection layer EIL on a side of the electron transport layer ETL away from the light emitting layer EML.

In some implementations, the electron transport layer ETL is generally made of an aromatic heterocyclic compound, such as an imidazole derivative (e.g., a benzimidazole derivative, an imidazopyridine derivative, a benzimidazophenanthridine derivative, etc.); an oxazine derivative (e.g., a pyrimidine derivative, a triazine derivative, etc.); and a compound containing a nitrogen-containing six-membered ring structure, e.g., a quinoline derivative, an isoquinoline derivative, a phenanthroline derivative, etc. (further including a compound having a phosphine oxide series substituent in a heterocyclic ring, e.g., OXD-7, TAZ, p-EtTAZ, BPhen, BCP).

In some implementations, the material of the electron transport layer ETL includes any one of: a benzimidazole derivative, an imidazopyridine derivative, a benzimidazophenanthridine derivative, a pyrimidine derivative, a triazine derivative, a quinoline derivative, an isoquinoline derivative, and a phenanthroline derivative. Here, the electron transport layer ETL made of the material with the low refractive index can ensure the gain for the light emitting wavelength under the microcavity effect of the light emitting device.

Illustratively, the material of the electron transport layer ETL includes a host material and a dopant material, where the host material may be TPBi, which has the following structure:

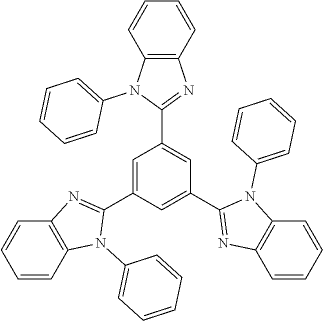 [SMILES: c1ccc(-n2c(-c3cc(-c4nc5ccccc5n4-c4ccccc4)cc(-c4nc5ccccc5n4-c4ccccc4)c3)nc3ccccc32)cc1]

The dopant material has the following structure:

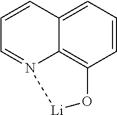

Illustratively, the host material of the electron transport layer ETL may alternatively be BPhen, which has the following structure:

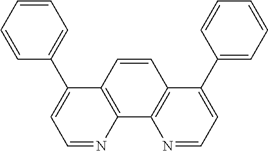 [SMILES: c1ccc(-c2ccnc3c2ccc2c(-c4ccccc4)ccnc23)cc1]

The dopant material has the following structure:

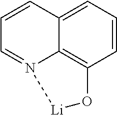

It should be noted that the OLED device may be divided into a bottom emission OLED device and a top emission OLED device depending on a light outgoing direction. In the bottom emission device, light is emitted from a substrate, a reflective electrode is located above an organic light emitting layer EML, and a transparent electrode is located below the organic light emitting layer EML. A thin film transistor in the bottom emission OLED device cannot transmit light therethrough, resulting in a small light emitting area. In the top emission device, the transparent electrode is located above the organic light emitting layer EML and the reflective electrode is located below the organic light emitting layer EML, so that light is emitted from a direction opposite to the substrate, thereby increasing the light transmission area.

The light emitting device provided by the embodiment of the present disclosure is mainly the top emission device. As an example, the light emitting devices are all top emission devices below.

In some implementations, as shown in FIG. 2, the light emitting device further includes a plurality of capping layers stacked on a side of the second electrode 2 away from the first electrode 1; at least part of the plurality of capping layers is a first capping layer CPL1, the rest is a second capping layer CPL2, and a refractive index of the first capping layer CPL1 is different from that of the second capping layer CPL2.

Here, the light outgoing mode is changed in combination with the plurality of capping layers with different refractive indexes, so that light originally limited in the resonant microcavity can be emitted from the second electrode 2, and the light extraction efficiency of the light emitting device is improved.

In some implementations, the refractive index of the first capping layer CPL1 is greater than that of the second capping layer CPL2; the first capping layer CPL1 is closer to the second electrode 2 than the second capping layer CPL2.

In some implementations, the refractive index of the first capping layer CPL1 is between 1.95 and 2.31; the refractive index of the second capping layer CPL2 is between 1.618 and 1.703.

Illustratively, the plurality of capping layers includes one first capping layer CPL1 and one second capping layer CPL2, and the first capping layer CPL1 is closer to the second electrode 2 than the second capping layer CPL2. The refractive index of the first capping layer CPL1 is larger than that of the second capping layer CPL2. With such capping layers with high and low refractive indexes respectively, the light originally limited in the light emitting device is emitted more easily, so that the light emitting device shows a higher light extraction efficiency.

In some implementations, the light emitting device is the blue light emitting device 01; an optical thickness of the first capping layer CPL1 is between 1300 Å and 1600 Å, and an optical thickness of the second capping layer CPL2 is between 1100 Å and 1500 Å. Here, the range of the optical thickness of the first capping layer CPL1 and the range of the optical thickness of the second capping layer CPL2 are specifically provided, so that blue light limited in the blue light emitting device 01 can be efficiently extracted.

In some implementations, the light emitting device is the green light emitting device 02; an optical thickness of the first capping layer CPL1 is between 1200 Å and 1500 Å, and an optical thickness of the second capping layer CPL2 is between 1000 Å and 1400 Å. Here, the range of the optical thickness of the first capping layer CPL1 and the range of the optical thickness of the second capping layer CPL2 are specifically provided, so that green light limited in the green light emitting device 02 can be efficiently extracted.

In some implementations, the light emitting device is the red light emitting device 03; an optical thickness of the first capping layer CPL1 is between 1100 Å and 1400 Å, and an optical thickness of the second capping layer CPL2 is between 900 Å and 1300 Å. Here, the range of the optical thickness of the first capping layer CPL1 and the range of the optical thickness of the second capping layer CPL2 are specifically provided, so that red light limited in the red light emitting device 03 can be efficiently extracted.

In some implementations, a general structural formula (I) of the material of the first capping layer CPL1 is as follows:

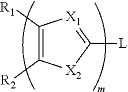

Where m is equal to 2; L represents any one of phenylene, biphenylene, naphthylene, a general structural formula (II), a general structural formula (III), a general structural formula (IV) and a general structural formula (V); X1 is N or CR, X2 is any one of S, O and NR, where R in CR, R in NR, R1 and R2 independently are represented to be selected from one of the following: hydrogen, deuterium, a substituted or unsubstituted alkyl group, a substituted or unsubstituted cycloalkyl group, a substituted or unsubstituted heterocyclic group, a substituted or unsubstituted alkenyl group, a substituted or unsubstituted cycloalkenyl group, a substituted or unsubstituted alkynyl group, a substituted or unsubstituted alkoxy group, a substituted or unsubstituted alkylthio group, a substituted or unsubstituted aryl ether group, a substituted or unsubstituted aryl thioether group, a substituted or unsubstituted C6 to C60 aryl group, a substituted or unsubstituted C6 to C60 heteroaryl group, a substituted or unsubstituted carbonyl group, a substituted or unsubstituted oxycarbonyl group, a substituted or unsubstituted carbamoyl group, a substituted or unsubstituted silane group, a substituted or unsubstituted alkylamine group, and a substituted or unsubstituted aryl amido group;
The general structural formula (II):

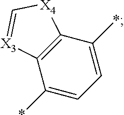

The general structural formula (III):

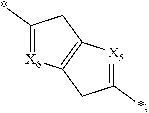

The general structural formula (IV):

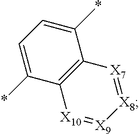

The general structural formula (V):

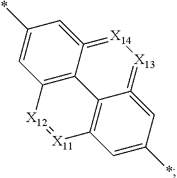

where, X₃ represents N or CR; X₄ represents S, O or NR; X₅ and X₆ each independently represent S or O; X₇, X₈, X₉, X₁₀ each independently represent N or CR, and at least one of X₇, X₈, X₉, X₁₀ is N; X₁, X₁₂, X₁₃, X₁₄ each independently represent N or CR, and at least two of X₁₁, X₁₂, X₁₃, X₁₄ are N; * denotes a position to which the general structural formula (I) is connected.

In some implementations, L may include any one of the following structures a to p:

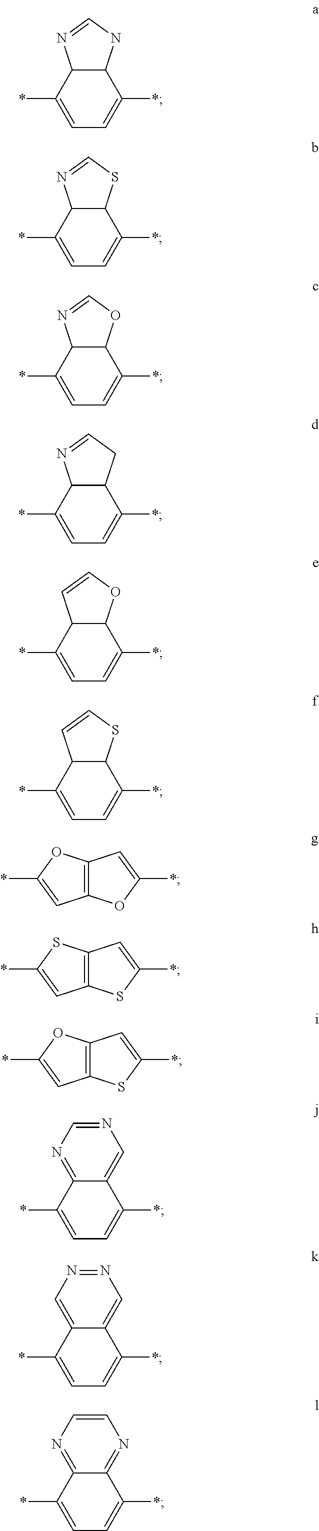

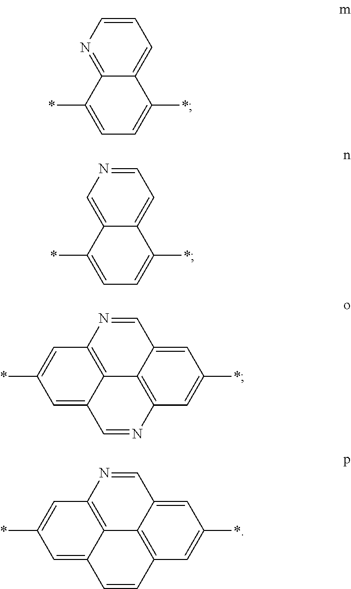

In some implementations, examples of the specific structure of the material of the first capping layer CPL1 may include any one of the following groups 1 to 48:

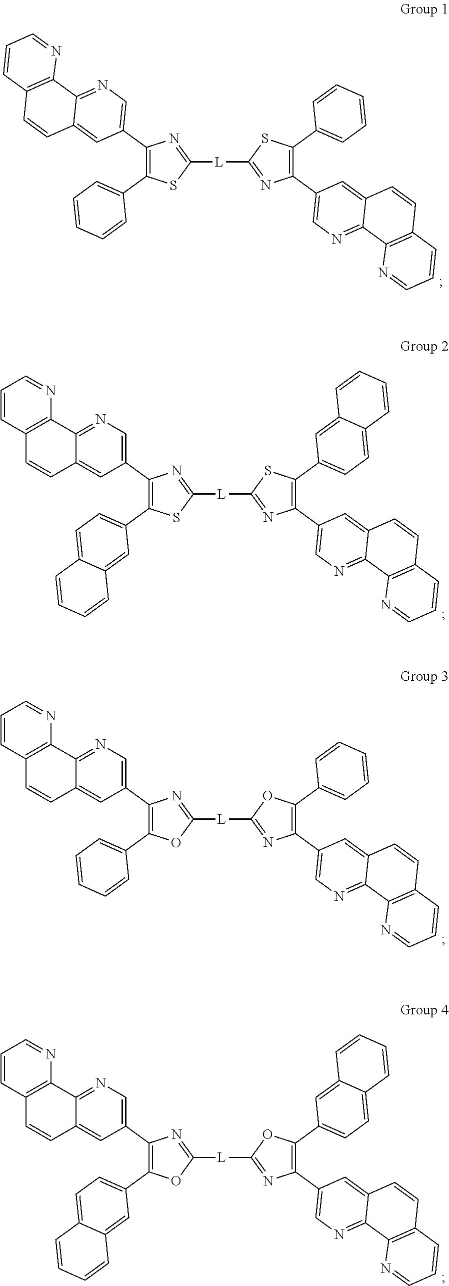

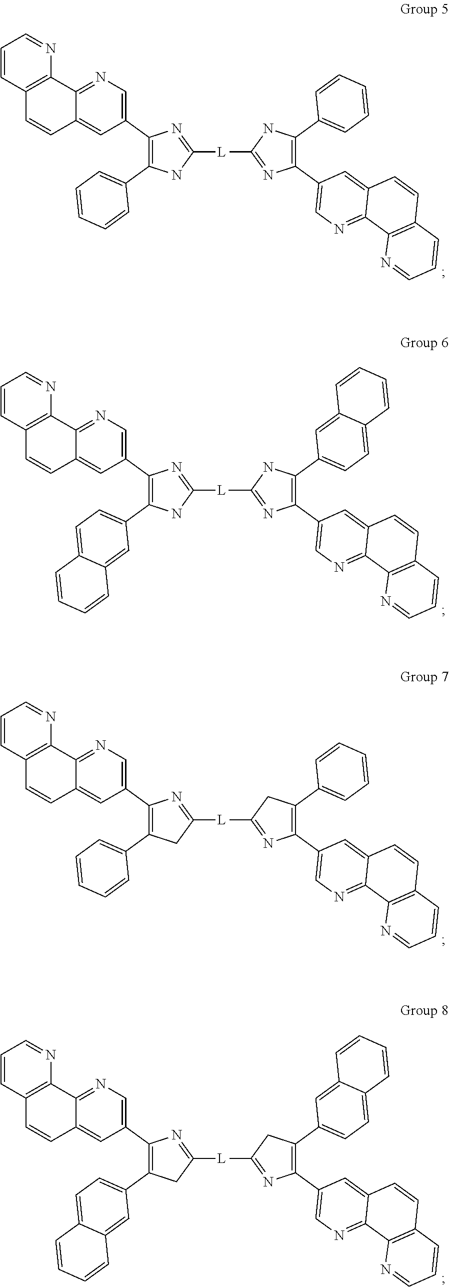

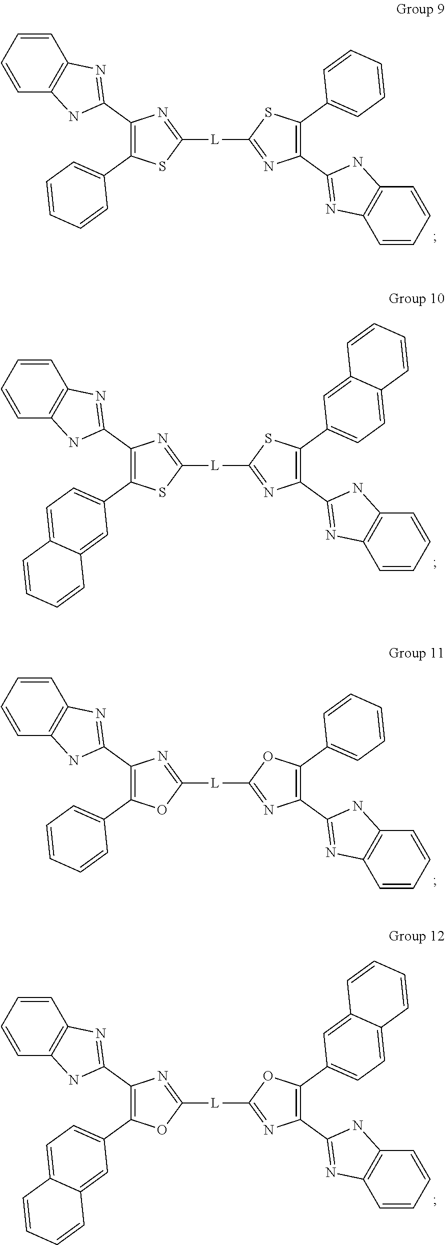

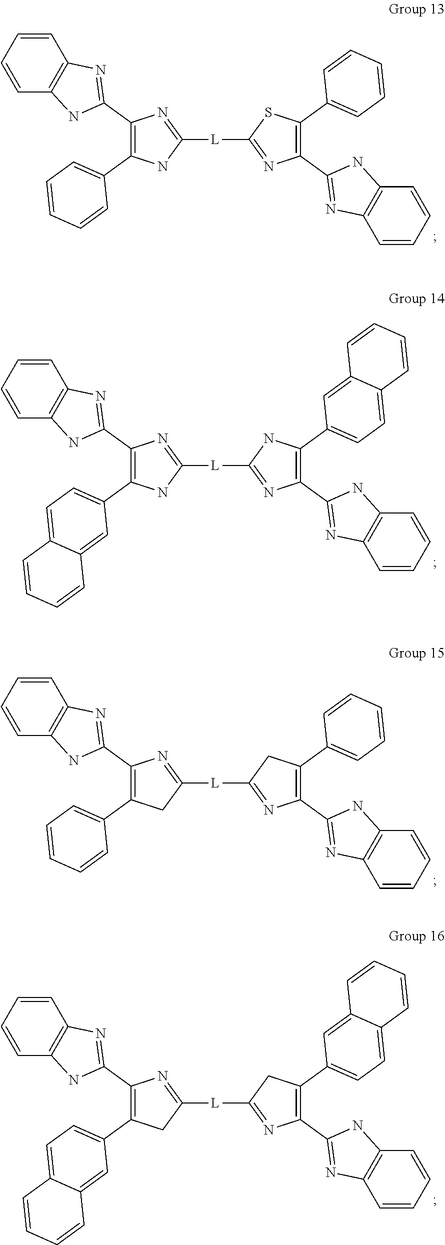

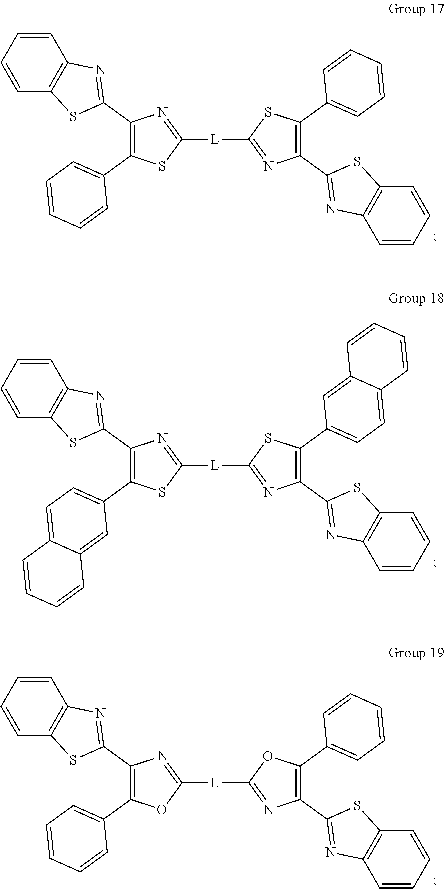

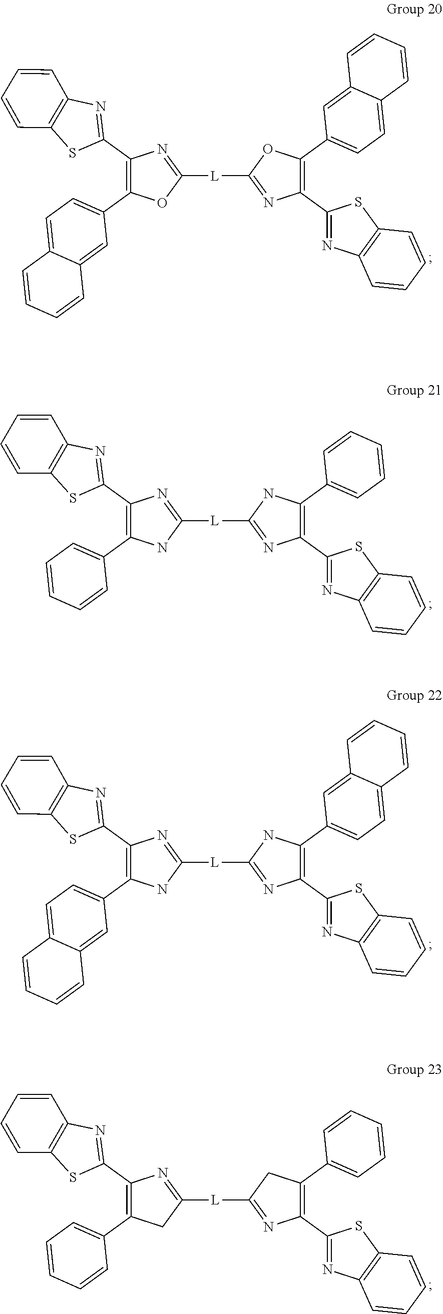

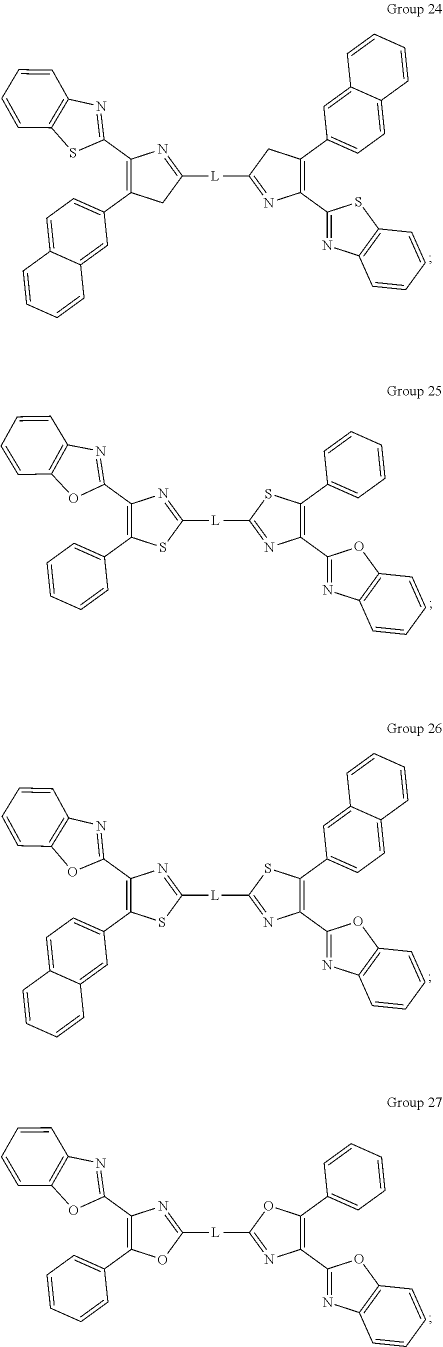

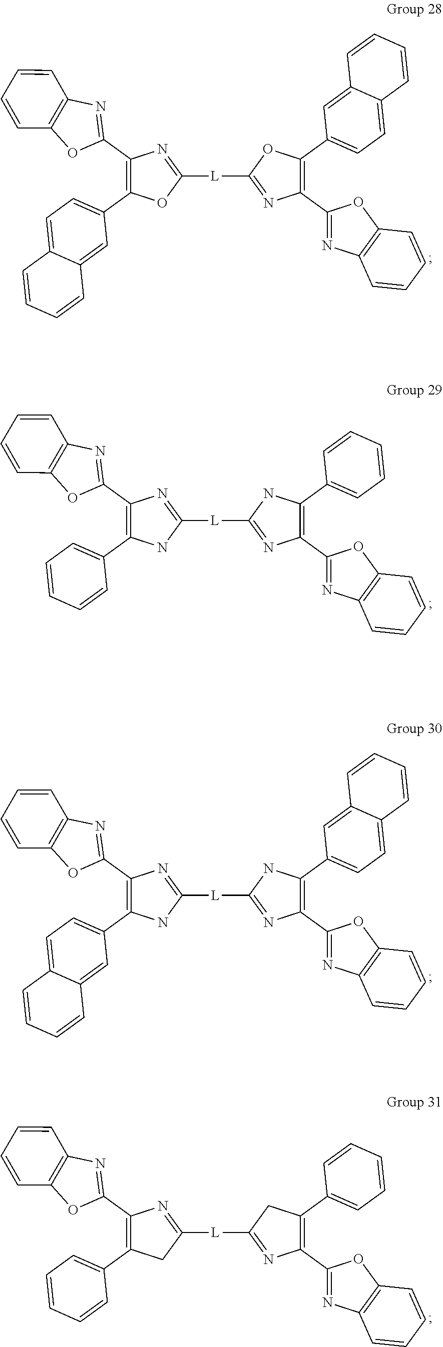

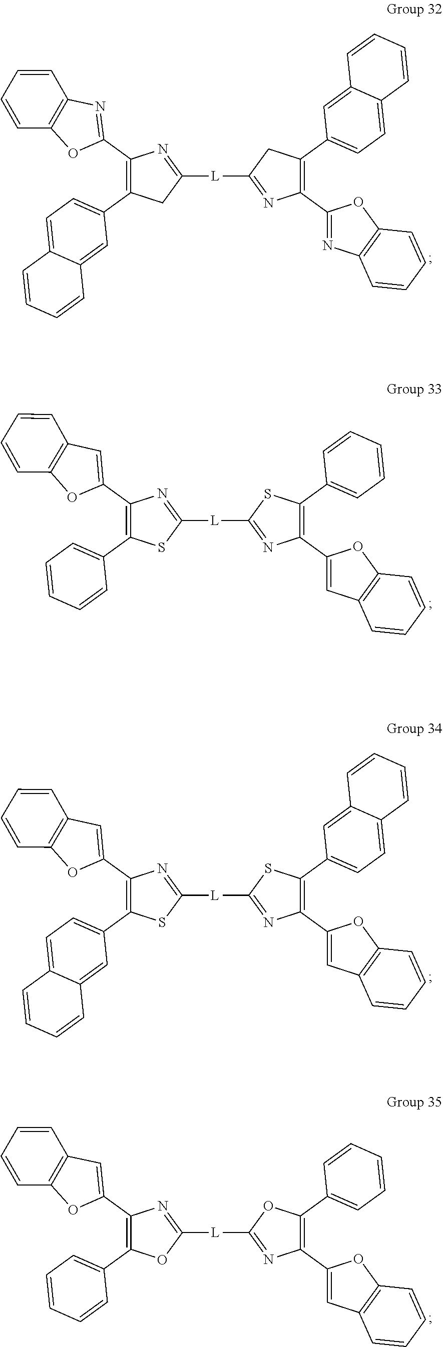

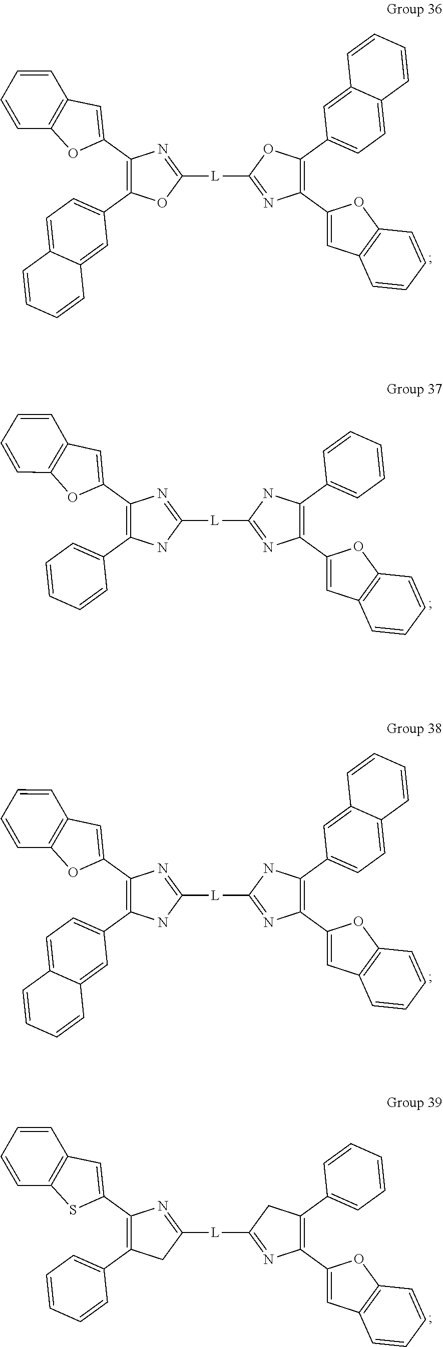

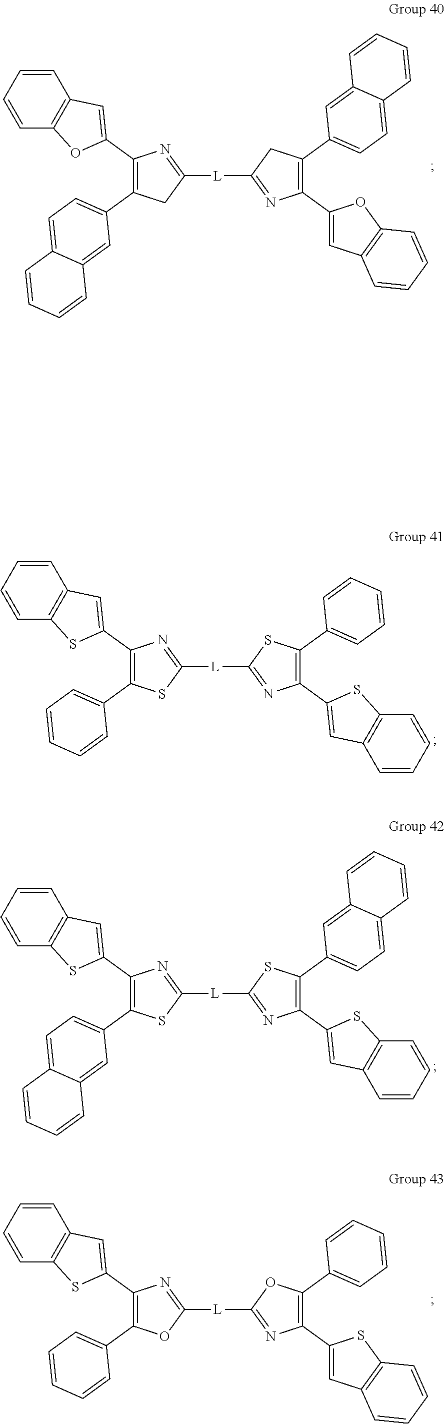

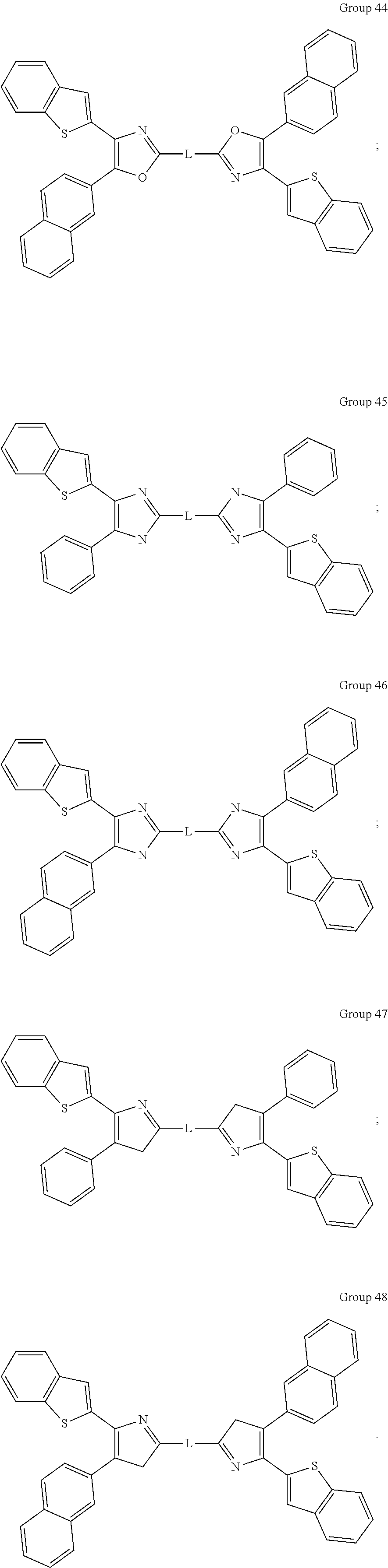

The formula (I)

$$\frac{{n}^{2} - 1}{{n}^{2} + 2} = \frac{4}{3} π \frac{{P}_{λ}}{V}$$

is known, where n represents the refractive index; λ represents a wavelength of irradiated light; P_{λ} represents a polarization rate; V represents a volume of a molecule. It can be seen from the formula (I) that the polarization rate and the volume of the molecule are important parameters for affecting the refractive index.

Heteroatoms such as S, O, N, etc. are introduced into the molecules of the material of the first capping layer CPL1, so that the polarizability is high, the polarization rate is higher, and the refractive index is higher as can be seen from the formula (I); in addition, strong intermolecular interaction force exists among nitrogen heterocyclic molecules in the material of the first capping layer CPL1, so that the ordered orientation of the molecules in the first capping layer CPL1 is facilitated to a certain extent, the number of molecules in a unit volume is increased, and the refractive index is increased. Here, the first capping layer CPL1 having a high refractive index can effectively improve the light coupling efficiency of the light emitting device, thereby improving the light outgoing mode, so that the light emitting device has the higher light extraction efficiency. In addition, the nitrogen heterocyclic compound in the material of the first capping layer CPL1 has a low absorption coefficient in the visible light region, thus cannot significantly absorb light emitted by the light emitting device, and cannot affect the light color of the light emitting device and can avoid color shift.

Illustratively, the material of the first capping layer CPL1 is indicated by means of a “number-letter” representation. The “number” in the “number-letter” indicates the number of groups of the material of the first capping layer CPL1, and the “letter” indicates the structure of L. The refractive indexes of the different materials of the first capping layer CPL1 at different wavelengths of light are shown in table 1:

TABLE 1

| | Refractive index | | |
|---|---|---|---|
| CPL1 | @460 nm | @530 nm | @620 nm |
| 1-b | 2.27 | 2.15 | 2.06 |
| 9-b | 2.17 | 2.08 | 2.01 |
| 17-b | 2.31 | 2.21 | 2.13 |
| 25-b | 2.26 | 2.18 | 2.09 |
| 33-b | 2.19 | 2.10 | 2.04 |
| 41-b | 2.22 | 2.14 | 2.05 |
| 1-h | 2.26 | 2.15 | 2.08 |
| 9-h | 2.18 | 2.08 | 1.99 |
| 17-h | 2.27 | 2.19 | 2.11 |
| 25-h | 2.11 | 2.03 | 1.95 |
| 33-h | 2.25 | 2.18 | 2.12 |
| 41-h | 2.21 | 2.16 | 2.11 |

Here, an ellipsometer may be employed for measuring the refractive index. Since a medium has different refractive indexes for different wavelengths of light, the ellipsometer is used to measure the refractive indexes for different wavelengths of light. Specifically, a scanning range of the ellipsometer for the wavelength of light may range from 245 nm to 1000 nm; the material of the first capping layer CPL1 is evaporated on a silicon wafer, and a film thickness of the material is 50 nm.

In some implementations, the general structural formula (VI) of the material of the second capping layer CPL2 is as follows:
the general structural formula (VI):

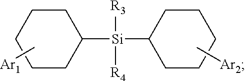

where, Ar₁ represents a structure of a general structural formula (VII) or (VIII), Ar₂ represents the structure of the general structural formula (VII) or (VIII);
the general structural formula (VII):

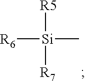

the general structural formula (VIII):

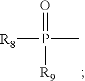

where, R₃, R₄, R₅, R₆, R₇, R₈, and Ry each independently represent one of the following: a substituted or unsubstituted alkyl group, a substituted or unsubstituted cycloalkyl group, a substituted or unsubstituted heterocyclic group, a substituted or unsubstituted alkenyl group, a substituted or unsubstituted cycloalkenyl group, a substituted or unsubstituted alkynyl group, a substituted or unsubstituted alkoxy group, a substituted or unsubstituted alkylthio group, a substituted or unsubstituted aryl ether group, a substituted or unsubstituted aryl thioether group, a substituted or unsubstituted C6 to C60 aryl group, a substituted or unsubstituted C6 to C60 heteroaryl group, a substituted or unsubstituted carbonyl group, a substituted or unsubstituted oxycarbonyl group, a substituted or unsubstituted carbamoyl group, a substituted or unsubstituted silane group, a substituted or unsubstituted alkylamine group, and a substituted or unsubstituted aryl amido group.

In some implementations, a part of hydrogen in any one of the following structures independently represented by R₃, R₄, R₅, R₆, R₇, R₈, and R₉ is substituted by deuterium: a substituted or unsubstituted alkyl group, a substituted or unsubstituted cycloalkyl group, a substituted or unsubstituted heterocyclic group, a substituted or unsubstituted alkenyl group, a substituted or unsubstituted cycloalkenyl group, a substituted or unsubstituted alkynyl group, a substituted or unsubstituted alkoxy group, a substituted or unsubstituted alkylthio group, a substituted or unsubstituted aryl ether group, a substituted or unsubstituted aryl thioether group, a substituted or unsubstituted C6 to C60 aryl group, a substituted or unsubstituted C6 to C60 heteroaryl group, a substituted or unsubstituted carbonyl group, a substituted or unsubstituted oxycarbonyl group, a substituted or unsubstituted carbamoyl group, a substituted or unsubstituted silane group, a substituted or unsubstituted alkylamine group, and a substituted or unsubstituted aryl amido group.

In some implementations, Ar₁ and Ar₂ both include any one of the following structures q to w:

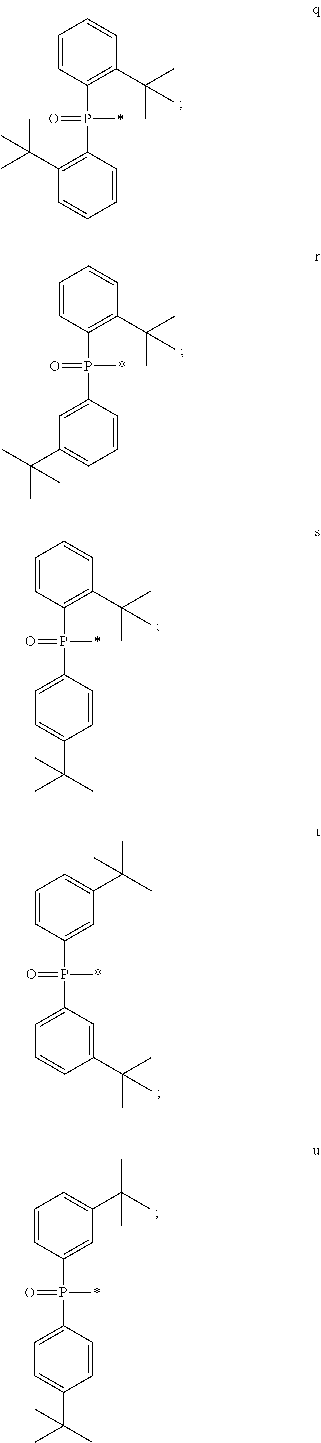

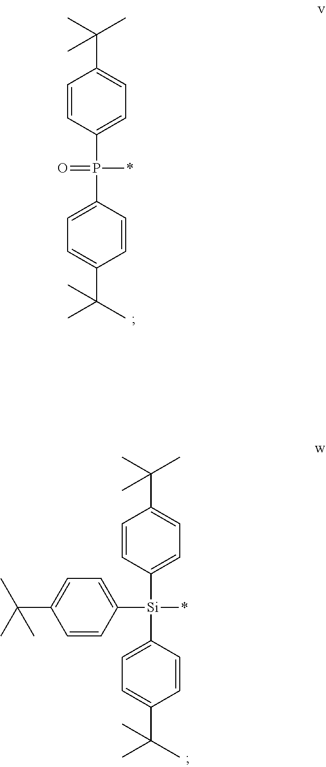 [SMILES: *P(=O)(c1ccc(C(C)(C)C)cc1)c1ccc(C(C)(C)C)cc1 ; *[Si](c1ccc(C(C)(C)C)cc1)(c1ccc(C(C)(C)C)cc1)c1ccc(C(C)(C)C)cc1]

where, * denotes a position to which the general structural formula (VI) is connected.

In some implementations, the structure of the material of the second capping layer CPL2 includes any one of the following groups 49 to 66:

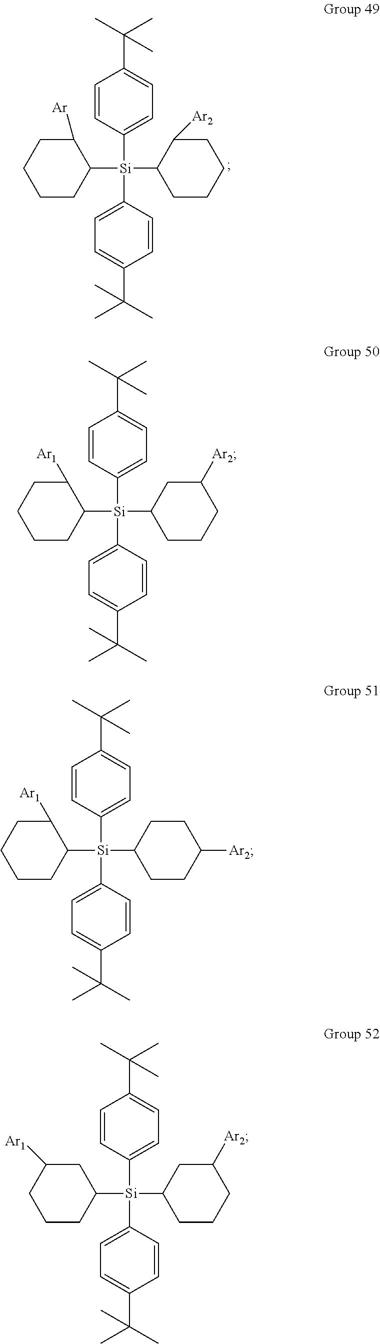

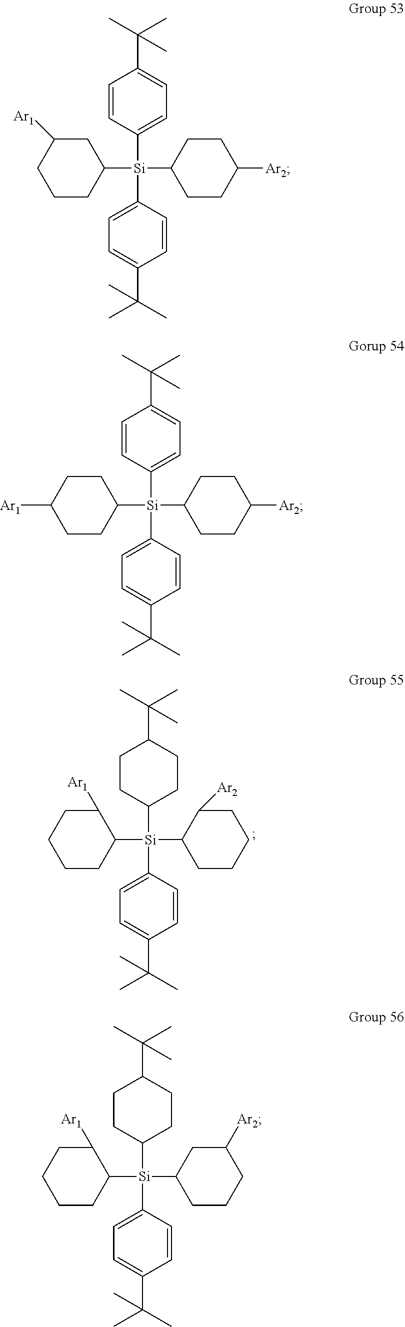

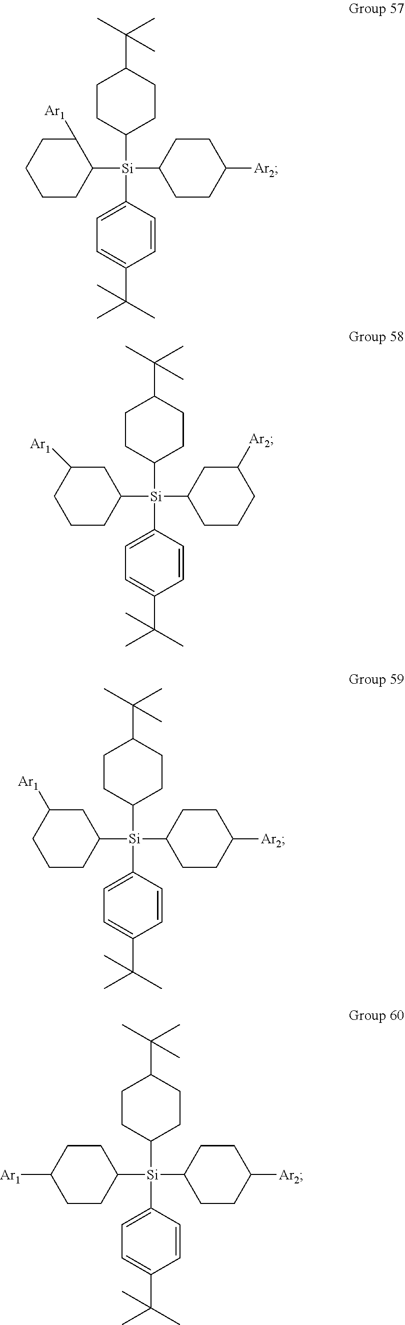

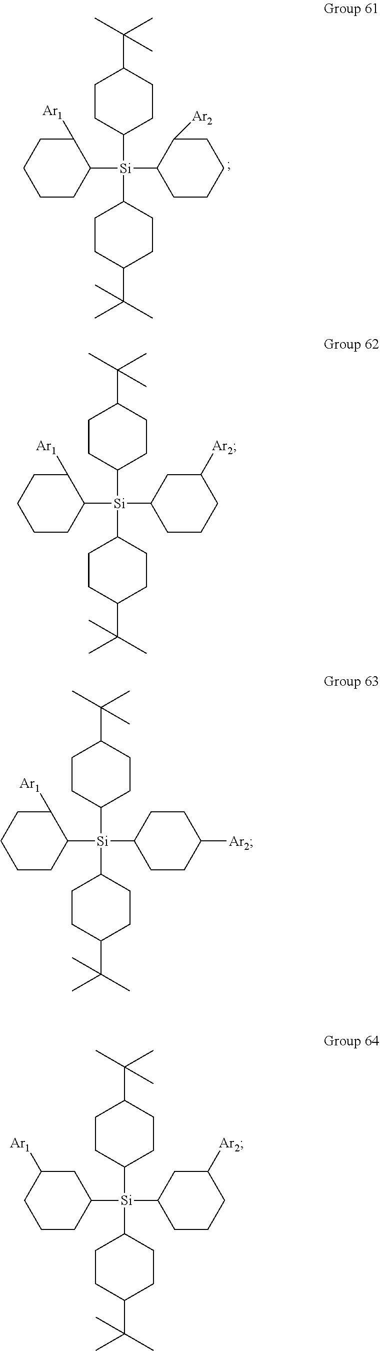

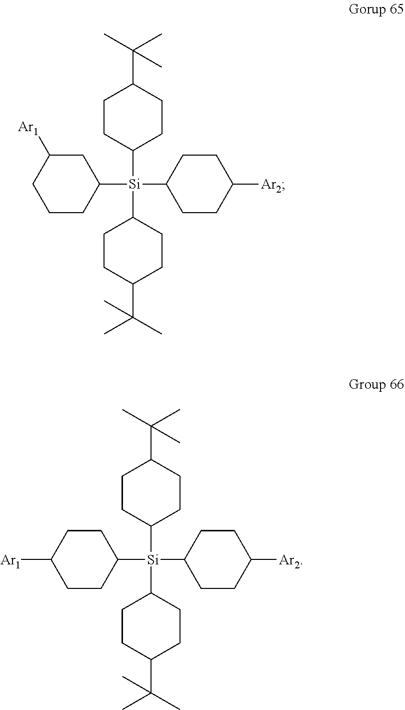

Si atoms and phosphorus-oxygen groups are introduced into molecules of the material of the second capping layer CPL2, so as to break conjugation and reduce the polarization rate of the molecule, and the refractive index is reduced as can be seen from the formula (I); in addition, a part of the molecule of the material of the second capping layer CPL2 is substituted by a alkyl group (specifically, a tertiary butyl in the alkyl group), so that the volume of the molecule is increased. The tertiary butyl may twist the molecules, which facilitates the disordered arrangement of the molecules in the second capping layer CPL2, thereby reducing the refractive index.

Illustratively, the material of the second capping layer CPL2 is indicated by means of a “number-letter 1-letter 2”. The “number” in the “number-letter 1-letter 2” indicates the number of groups of the material of the second capping layer CPL2, the “letter 1” indicates the structure of the Ar1 and the “letter 2” indicates the structure of the Ar2. The refractive indexes of different materials of the second capping layer CPL2 at different wavelengths of light are shown in table 2:

TABLE 2

| | Refractive index | | |
|---|---|---|---|
| CPL2 | @460 nm | @530 nm | @620 nm |
| 53-q-q | 1.684 | 1.662 | 1.657 |
| 54-r-r | 1.652 | 1.644 | 1.637 |
| 59-s-s | 1.633 | 1.625 | 1.618 |
| 60-t-t | 1.695 | 1.686 | 1.677 |
| 65-u-u | 1.703 | 1.692 | 1.684 |
| 66-v-v | 1.656 | 1.647 | 1.639 |
| 53-w-w | 1.674 | 1.667 | 1.622 |
| 54-w-w | 1.689 | 1.680 | 1.673 |
| 59-w-w | 1.674 | 1.665 | 1.659 |
| 60-w-w | 1.681 | 1.674 | 1.666 |
| 65-w-w | 1.647 | 1.640 | 1.635 |
| 66-w-w | 1.662 | 1.653 | 1.647 |

Here, an ellipsometer may be employed for measuring the refractive index. Since the medium has different refractive indexes for different wavelengths of light, the ellipsometer is used to measure the refractive indexes for different wavelengths of light. Specifically, the scanning range of the ellipsometer for the wavelength of light may range from 245 nm to 1000 nm; the material of the second capping layer CPL2 is evaporated on a silicon wafer, and a film thickness of the material is 50 nm.

Illustratively, a magnitude of a glass transition temperature (Tg) determines the thermal stability of the material during evaporation, and the higher the Tg is, the better the thermal stability of the material is. A measuring instrument is a differential scanning calorimeter (DSC); the test atmosphere is nitrogen gas, the heating rate is 10° C./min, and the temperature is in a range from 50° C. to 300° C. The measured glass transition temperatures (Tg) for the first and second capping layers CPL1 and CPL2 are shown in table 3:

TABLE 3

| CPL1 | Tg (° C.) | CPL2 | Tg (° C.) |
|---|---|---|---|
| 1-b | 141 | 53-q-q | 111 |
| 9-b | 132 | 54-r-r | 103 |
| 17-b | 129 | 59-s-s | 117 |
| 25-b | 135 | 60-t-t | 121 |
| 33-b | 140 | 65-u-u | 117 |
| 41-b | 137 | 66-v-v | 109 |
| 1-h | 139 | 53-w-w | 106 |
| 9-h | 137 | 54-w-w | 114 |
| 17-h | 131 | 59-w-w | 113 |
| 25-h | 145 | 60-w-w | 118 |
| 33-h | 136 | 65-w-w | 110 |
| 41-h | 130 | 66-w-w | 112 |

As can be seen from table 3, rigid groups are introduced into the selected material of the first capping layer CPL1 and the selected material of the second capping layer CPL2 in the embodiments of the present disclosure, which can advantageously increase the glass transition temperature (Tg) of the molecule, so that the thermal stabilities of the first capping layer CPL1 and the second capping layer CPL2 is ensured, and the stability of the light emitting device is further improved.

In some implementations, the first electrode 1, i.e., the anode, may be made of an electrode material with a high work function, such as transparent oxides ITO, IZO, and the like. Alternatively, a composite electrode, which is formed of ITO/Ag/ITO, Ag/IZO, CNT/ITO, CNT/IZO, GO/ITO, GO/IZO, or the like, may also be used. “/” indicates that the materials before and after the “/” are stacked sequentially.

In some implementations, a material of the hole injection layer HIL may be selected from inorganic oxides, such as: molybdenum oxide, titanium oxide, vanadium oxide, rhenium oxide, ruthenium oxide, chromium oxide, zirconium oxide, hafnium oxide, tantalum oxide, silver oxide, tungsten oxide, manganese oxide, and the like. Alternatively, dopants of strong electron-withdrawing systems, such as F4TCNQ, HATCN, PPDN, etc., may be used. Alternatively, P-type doping may be performed in the hole transport material, and then the hole injection layer HIL may be formed by co-evaporation.

Illustratively, the material of the hole injection layer HIL may be HATCN, which has the following structure:

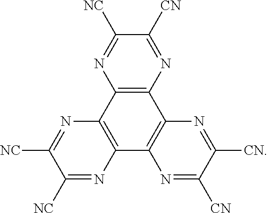 [SMILES: N#Cc1nc2c3nc(C#N)c(C#N)nc3c3nc(C#N)c(C#N)nc3c2nc1C#N]

As another example, the material of the hole injection layer HIL may be F4TCNQ, and the structure of F4TCNQ is as follows:

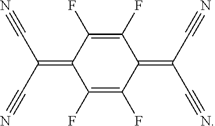 [SMILES: N#CC(C#N)=c1c(F)c(F)c(=C(C#N)C#N)c(F)c1F]

As another example, the material of the hole injection layer HIL may be PPDN, and the structure of PPDN is as follows:

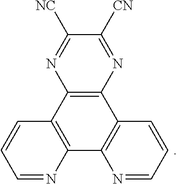 [SMILES: N#Cc1nc2c3cccnc3c3ncccc3c2nc1C#N]

In some implementations, the material of the hole transport layer HTL may be selected from arylamine materials or carbazole materials, such as NPB, TPD, BAFLP, DFLDPBi, TCTA, TAPC, and the like, which have good hole transport properties.

Illustratively, the material of the hole transport layer HTL may be NPB, which has the following structure:

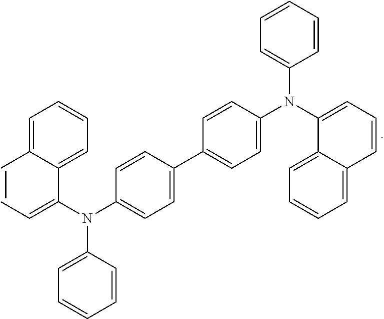

As another example, the material of the hole transport layer HTL may be TCTA, which has the following structure:

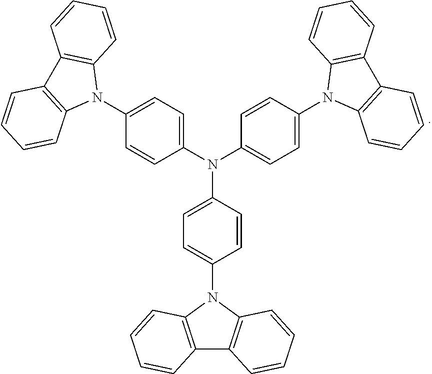 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

As another example, the material of the hole transport layer HTL may be TAPC, which has the following structure:

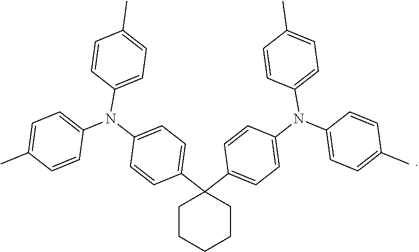

In some implementations, the material of the electron blocking layer EBL may be selected from arylamine materials or carbazole materials, such as CBP or PCzPA, which have a good hole transport property. The electron blocking layer EBL here may be any one of a red electron blocking layer EBL, a green electron blocking layer EBL, and a blue electron blocking layer EBL.

Illustratively, a structure of the material of the blue electron blocking layer EBL is as follows:

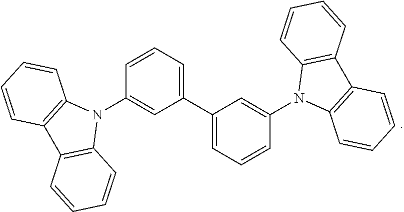 [SMILES: c1cc(-c2cccc(-n3c4ccccc4c4ccccc43)c2)cc(-n2c3ccccc3c3ccccc32)c1]

Illustratively, a structure of the material of the green electron blocking layer EBL is as follows:

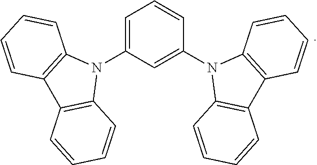 [SMILES: c1cc(-n2c3ccccc3c3ccccc32)cc(-n2c3ccccc3c3ccccc32)c1]

Illustratively, a structure of the material of the red electron blocking layer EBL is as follows:

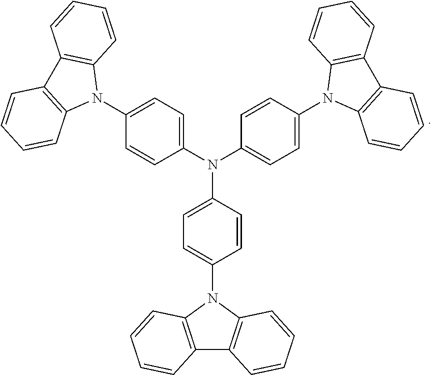 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

In some implementations, a material of the light emitting layer EML includes a host material and a guest material (i.e., a dopant). Specifically, the material of the light emitting layer EML may be selected from a phosphorescent host material, and be selected from a phosphorescent dopant. Alternatively, the material of the light emitting layer EML may be selected from a fluorescent host material and be selected from a fluorescent dopant. Here, the host material may contain only one material, or may contain a mixture of two or more materials.

Illustratively, the light emitting device is the blue light emitting device 01; the host material of the blue light emitting layer B-EML may be selected from anthracene derivatives ADN, MADN, and the like; the guest material of the blue light emitting layer B-EML may be selected from pyrene derivatives, fluorene derivatives, perylene derivatives, styrylamine derivatives, metal complexes, etc., such as TBPe, BDAVBi, DPAVBi, FIrpic, etc.

Illustratively, the host material of the blue light emitting layer B-EML may be AND, which has the following structure:

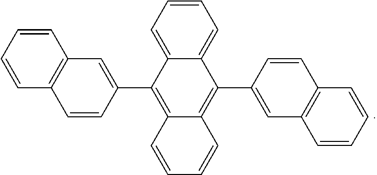 [SMILES: c1ccc2cc(-c3c4ccccc4c(-c4ccc5ccccc5c4)c4ccccc34)ccc2c1]

The guest material of the blue light emitting layer B-EML may be DPAVBi, which has the following structure:

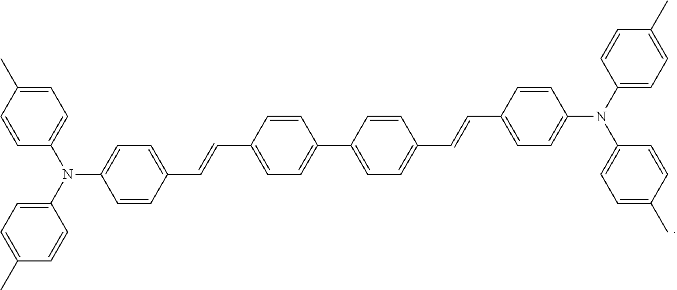 [SMILES: Cc1ccc(N(c2ccc(C)cc2)c2ccc(/C=C/c3ccc(-c4ccc(/C=C/c5ccc(N(c6ccc(C)cc6)c6ccc(C)cc6)cc5)cc4)cc3)cc2)cc1]

Illustratively, the light emitting device is the green light emitting device 02; the host material of the green light emitting layer G-EML may be selected from coumarin dyes, quinacridone derivatives, polycyclic aromatic hydrocarbons, diamine anthracene derivatives, carbazole derivatives, and the like, such as DMQA, BA-NPB, Alq3, and the like. The guest material of the green light emitting layer G-EML may be selected from metal complexes, etc., such as Ir(ppy)3, Ir(ppy)2(acac) etc.

Illustratively, the host material of the green light emitting layer G-EML includes two materials having the following structures:

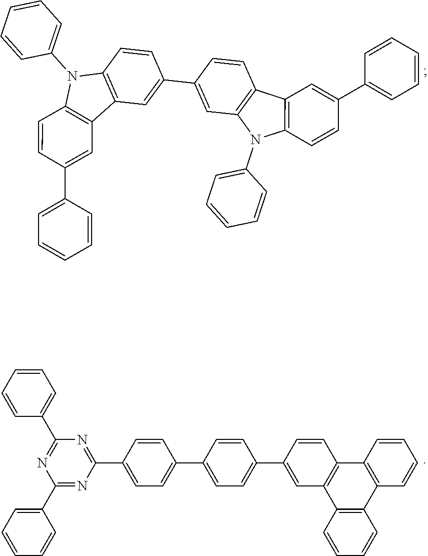 [SMILES: c1ccc(-c2ccc3c(c2)c2cc(-c4ccc5c6cc(-c7ccccc7)ccc6n(-c6ccccc6)c5c4)ccc2n3-c2ccccc2)cc1 ; c1ccc(-c2nc(-c3ccccc3)nc(-c3ccc(-c4ccc(-c5ccc6c7ccccc7c7ccccc7c6c5)cc4)cc3)n2)cc1]

The guest material of the green light emitting layer G-EML may be Ir(ppy)3, which has the following structure:

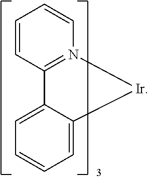

Illustratively, the light emitting device is the red light emitting device 03; the host material of the red light emitting layer R-EML may be selected from DCM series materials such as DCM, DCJTB, DCJTI, etc.; the guest material of the red light emitting layer R-EML may be selected from metal complexes, etc., such as Ir(piq)2(acac), PtOEP, Ir(btp)2(acac) etc.

Illustratively, the host material of the red light emitting layer R-EML includes two materials having the following structures:

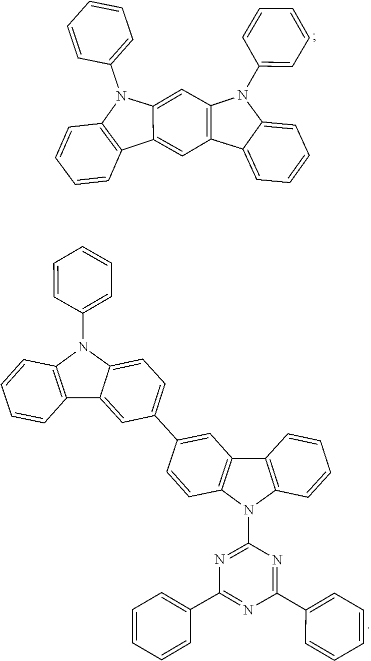 [SMILES: c1ccc(-n2c3ccccc3c3cc4c5ccccc5n(-c5ccccc5)c4cc32)cc1 ; c1ccc(-c2nc(-c3ccccc3)nc(-n3c4ccccc4c4cc(-c5ccc6c(c5)c5ccccc5n6-c5ccccc5)ccc43)n2)cc1]

The guest material of the red light emitting layer R-EML may be Ir(piq)2(acac), which has the following structure:

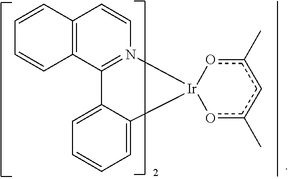

Alternatively, the guest material of the red light emitting layer R-EML may also have the following structure:

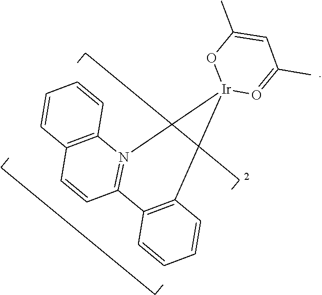

In some implementations, the hole blocking layer HBL is generally made of an aromatic heterocyclic compound, such as an imidazole derivative (e.g., a benzimidazole derivative, an imidazopyridine derivative, a benzimidazophenanthridine derivative, etc.); an oxazine derivative (e.g., a pyrimidine derivative, a triazine derivative, etc.); and a compound containing a nitrogen-containing six-membered ring structure, e.g., a quinoline derivative, an isoquinoline derivative, a phenanthroline derivative, etc. (further including a compound having a phosphine oxide series substituent in a heterocyclic ring, e.g., OXD-7, TAZ, p-EtTAZ, BPhen, BCP).

Illustratively, a structure of the material of the hole blocking layer HBL is as follows:

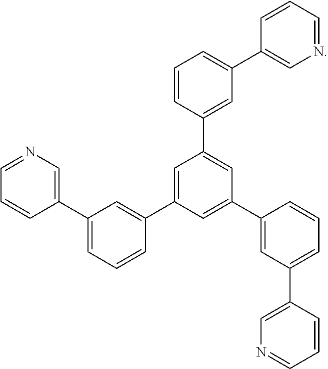 [SMILES: c1cncc(-c2cccc(-c3cc(-c4cccc(-c5cccnc5)c4)cc(-c4cccc(-c5cccnc5)c4)c3)c2)c1]

In some implementations, the material of the electron injection layer EIL may be selected from materials having an electron transport ability, and having an effect of injecting electrons from the cathode. The material having an excellent film-forming ability is generally an alkali metal or a metal such as LiF, Yb, Mg, Ca, or a compound thereof.

In some implementations, the second electrode 2, i.e. the cathode, may be made of a material with a low work function, so as to easily inject electrons into the organic layer, and has good light transmittance and electrical conductivity. Illustratively, the material of the cathode may be a metal, a metal oxide, a metal alloy, such as aluminum (Al), silver (Ag), gold (Au), magnesium (Mg), calcium (Ca), ytterbium (Yb), indium (In), lithium (Li), potassium (K), sodium (Na), tin (Sn), titanium (Ti), lead (Pb), samarium (Sm), yttrium (Y), Indium Tin Oxide (ITO), magnesium-silver alloy (Mg:Ag), ytterbium-gold alloy (Yb:Au), ytterbium-silver alloy (Yb:Ag), lithium-aluminum alloy (Li:Al), lithium-calcium-magnesium alloy (Li:Ca:Al), or the like; and lamination materials such as magnesium/aluminum (Mg/Al), magnesium/silver (Mg/Ag), aluminum/silver (Al/Ag), aluminum/gold (Al/Au), ytterbium/gold (Yb/Au), ytterbium/silver (Yb/Ag), calcium/magnesium (Ca/Mg), calcium/silver (Ca/Ag), barium/silver (Ba/Ag), and the like, but not limited thereto. Here, “/” indicates that the latter material is doped into the former material.

In some implementations, as shown in FIG. 2, for a thickness of each layer in the light emitting functional layer 3, specifically, a thickness of the hole injection layer HIL is between 5 nm and 30 nm, a thickness of the hole transport layer HTL is between 100 nm and 2000 nm, a thickness of the electron blocking layer EBL is between 5 nm and 100 nm, a thickness of the light emitting layer EML is between 20 nm and 100 nm, a thickness of the hole blocking layer HBL is between 5 nm and 100 nm, a thickness of the electron transport layer ETL is between 20 nm and 100 nm, and a thickness of the electron injection layer EIL is between 1 nm and 10 nm.

Illustratively, for the blue light emitting device 01, the thickness of the hole injection layer HIL is 10 nm; the thickness of the hole transport layer HTL was 100 nm; the thickness of the electron blocking layer EBL is 10 nm; the thickness of the blue light emitting layer B-EML is 20 nm, and a doping concentration of the guest material in the blue light emitting layer B-EML is 10%; the thickness of the hole blocking layer HBL is 5 nm; the thickness of the electron transport layer ETL is 40 nm, and a ratio of the host material to the guest material of the electron transport layer ETL is 1:1; the thickness of the electron injection layer EIL is 1 nm, a thickness of the cathode is 13 nm, a thickness of the first capping layer CPL1 is 50 nm, and a thickness of the second capping layer CPL2 is 70 nm.

Illustratively, for the green light emitting device 02, the thickness of the hole injection layer HIL is 10 nm; the thickness of the hole transport layer HTL is 100 nm; the thickness of the electron blocking layer EBL is 35 nm; the thickness of the green light emitting layer G-EML is 40 nm, and a doping concentration of the guest material in the green light emitting layer G-EML is 10%; the thickness of the hole blocking layer HBL is 5 nm; the thickness of the electron transport layer ETL is 40 nm, and a ratio of the host material to the guest material of the electron transport layer ETL is 1:1; the thickness of the electron injection layer EIL is 1 nm, a thickness of the cathode is 13 nm, a thickness of the first capping layer CPL1 is 50 nm, and a thickness of the second capping layer CPL2 is 70 nm.

Illustratively, for the red light emitting device 03, the thickness of the hole injection layer HIL is 10 nm; the thickness of the hole transport layer HTL is 100 nm; the thickness of the electron blocking layer EBL is 75 nm; the thickness of the red light emitting layer R-EML is 85 nm, and a doping concentration of the guest material in the red light emitting layer R-EML is 3%; the thickness of the hole blocking layer HBL is 5 nm; the thickness of the electron transport layer ETL is 40 nm, and a ratio of the host material to the guest material of the electron transport layer ETL is 1:1; the thickness of the electron injection layer EIL is 1 nm, a thickness of the cathode is 13 nm, a thickness of the first capping layer CPL1 is 50 nm, and a thickness of the second capping layer CPL2 is 70 nm.

The light emitting device provided by the embodiments of the present disclosure has been described as above.

An embodiment of the present disclosure further provides a method for manufacturing a light emitting device, which specifically includes the following steps S31 to S311:

At step S31, providing a base substrate.

The base substrate may be made of any transparent rigid or flexible substrate material, such as glass, polyimide, etc.

At step S32, forming an anode on the base substrate.

Illustratively, an ITO (the anode) is formed on a glass base, the glass plate with the ITO (the anode) is placed in a cleaning agent for ultrasonic treatment, washed in deionized water, ultrasonically degreased in an acetone-ethanol mixed solvent, and baked in a clean environment until the water is completely removed.

At step S33, forming a hole injection layer HIL on a side of the anode away from the base substrate.

Illustratively, the glass base with the anode is placed in a vacuum chamber, the vacuum chamber is vacuumized to 1×10⁻⁵ to 1×10⁻⁶ Pa, and a hole transport material is vacuum-evaporated on the anode layer to form the hole injection layer HIL.

At step S34, forming a hole transport layer HTL on a side of the hole injection layer HIL away from the anode.

Illustratively, a hole transport material is vacuum-evaporated on the hole injection layer HIL to form the hole transport layer HTL.

At step S35, forming an electron blocking layer EBL on a side of the hole transport layer HTL away from the hole injection layer HIL.

Illustratively, an electron blocking material is vacuum-evaporated on the hole injection layer HIL to form the electron blocking layer EBL.

At step S36, forming a light emitting layer EML on a side of the electron blocking layer EBL away from the hole transport layer HTL.

Illustratively, host materials and guest materials of the light emitting devices of corresponding colors are co-evaporated on the electron blocking layer EBL to form the light emitting layers EML of corresponding colors. By taking the blue light emitting layer B-EML as an example, a concentration of the host material in the blue light emitting layer B-EML is 97%, and a concentration of the guest material in the blue light emitting layer B-EML is 3%.

At step S37, forming a hole blocking layer HBL on a side of the light emitting layer EML away from the electron blocking layer EBL.

For example, a hole blocking material is vacuum-evaporated on the light emitting layer EML to form the hole blocking layer HBL.

At step S38, forming an electron transport layer ETL on a side of the hole blocking layer HBL away from the light emitting layer EML.

Illustratively, an electron transport material and Liq are co-evaporated on the hole blocking layer HBL, so that the electron transport material and the Liq are gasified at the same rate, to form the electron transport layer ETL.

At step S39, forming an electron injection layer EIL on a side of the electron transport layer ETL away from the hole blocking layer HBL.

Illustratively, a metal Yb is evaporated on the electron transport layer ETL to form the electron injection layer EIL.

At step S310, forming a cathode on a side of the electron injection layer EIL away from the electron transport layer ETL.

Illustratively, metals Mg and Ag are co-evaporated on the electron injection layer EIL to form the cathode.

At step S311, sequentially forming a first capping layer CPL1 and a second capping layer CPL2 on a side of the cathode away from the electron injection layer EIL.

Illustratively, any one of the materials in the groups 1 to 48 provided by the present disclosure is evaporated on the cathode to form the first capping layer CPL1, and any one of the materials in the groups 49 to 66 provided by the present disclosure is evaporated on the first capping layer CPL1 to form the second capping layer CPL2.

In some implementations, for light emitting devices of different colors, the functional sub-layers other than the light emitting layer EML and the electron blocking layer EBL in the light emitting functional layer 3 have the same thickness, and may be common.

Illustratively, for the blue light emitting device 01, the process of forming respective film layers includes: sequentially evaporating ITO, m-MTDATA (which serves as the host material of the hole injection layer) and F4TCNQ (which is a dopant) with a concentration of F4TCNQ being 3% and a total thickness thereof being 10 nm, m-MTDATA with a thickness of 100 nm, CBP with a thickness of 10 nm, BH and BD with a concentration of BD being 5% and a total thickness thereof being 20 nm, TPBI with a thickness of 5 nm, BCP and Liq with a ratio therebetween being 1:1 and a total thickness thereof being 30 nm, Yb with a thickness of 1 nm, Mg:Ag with a thickness of 13 nm and CPL (including CPL1 and CPL2) with a thickness of 60 nm.

In addition, an embodiment of the present disclosure further provides a display panel, including the light emitting device according to any one of the above embodiments. The display panel provided by the embodiment of the present disclosure has a remarkable advantage when being applied to a product having the display panel with a medium or small size, such as a mobile phone, a tablet computer, a vehicle-mounted device, a wearable device or the like.

In some implementations, the display panel includes three kinds of light emitting devices emitting light of different colors, such as a red light emitting device 03, a green light emitting device 02, and a blue light emitting device 01. The red light emitting device 03 may be the red light emitting device 03 in any one of the above embodiments; the green light emitting device 02 may be the green light emitting device 02 in any one of the above embodiments; the blue light emitting device 01 may be the blue light emitting device 01 in any one of the above embodiments.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A light emitting device, comprising a first electrode, a second electrode, and a light emitting functional layer between the first electrode and the second electrode, wherein the light emitting functional layer at least comprises an electron transport layer and a hole blocking layer;
the electron transport layer has a refractive index between 1.6 and 1.9, and an optical thickness in a range from 540 Å to 700 Å; and
a difference between the refractive index of the electron transport layer and a refractive index of the hole blocking layer is less than or equal to 0.1.

2. The light emitting device of claim 1, wherein the light emitting device is a blue light emitting device, and the electron transport layer has the refractive index between 1.7 and 1.9, and the optical thickness between 600 Å and 700 Å.

3. The light emitting device of claim 1, wherein the light emitting device is a green light emitting device, and the electron transport layer has the refractive index between 1.65 and 1.85, and the optical thickness between 570 Å and 670 Å.

4. The light emitting device of claim 1, wherein the light emitting device is a red light emitting device, and the electron transport layer has the refractive index between 1.6 and 1.8, and the optical thickness between 540 Å and 640 Å.

5. The light emitting device of claim 1, wherein a material of the electron transport layer comprises any one of:
a benzimidazole derivative, an imidazopyridine derivative, a benzimidazophenanthridine derivative, a pyrimidine derivative, a triazine derivative, a quinoline derivative, an isoquinoline derivative, and a phenanthroline derivative.

6. The light emitting device of claim 1, further comprising a plurality of capping layers stacked on a side of the second electrode away from the first electrode;
wherein at least part of the plurality of capping layers is a first capping layer, the rest is a second capping layer, and a refractive index of the first capping layer is different from that of the second capping layer.

7. The light emitting device of claim 6, wherein the refractive index of the first capping layer is greater than that of the second capping layer; and
the first capping layer is closer to the second electrode than the second capping layer.

8. The light emitting device of claim 7, wherein the refractive index of the first capping layer is between 1.95 and 2.31, and the refractive index of the second capping layer is between 1.618 and 1.703.

9. The light emitting device of claim 6, wherein the light emitting device is a blue light emitting device; and
an optical thickness of the first capping layer is between 1300 Å and 1600 Å, and an optical thickness of the second capping layer is between 1100 Å and 1500 Å.

10. The light emitting device of claim 6, wherein the light emitting device is a green light emitting device;
an optical thickness of the first capping layer is between 1200 Å and 1500 Å, and an optical thickness of the second capping layer is between 1000 Å and 1400 Å.

11. The light emitting device of claim 6, wherein the light emitting device is a red light emitting device;
an optical thickness of the first capping layer is between 1100 Å and 1400 Å, and an optical thickness of the second capping layer is between 900 Å and 1300 Å.

12. The light emitting device of claim 6, wherein a material of the first capping layer has the following general structural formula (I): 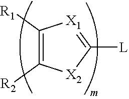
wherein, m is equal to 2; L represents any one of phenylene, biphenylene, naphthylene, a general structural formula (II), a general structural formula (III), a general structural formula (IV) and a general structural formula (V); X1 is N or CR, X2 is any one of S, O and NR, wherein R in CR, R in NR, R1 and R2 independently represent one of the following substances: hydrogen, deuterium, a substituted or unsubstituted alkyl group, a substituted or unsubstituted cycloalkyl group, a substituted or unsubstituted heterocyclic group, a substituted or unsubstituted alkenyl group, a substituted or unsubstituted cycloalkenyl group, a substituted or unsubstituted alkynyl group, a substituted or unsubstituted alkoxy group, a substituted or unsubstituted alkylthio group, a substituted or unsubstituted aryl ether group, a substituted or unsubstituted aryl thioether group, a substituted or unsubstituted C6 to C60 aryl group, a substituted or unsubstituted C6 to C60 heteroaryl group, a substituted or unsubstituted carbonyl group, a substituted or unsubstituted oxycarbonyl group, a substituted or unsubstituted carbamoyl group, a substituted or unsubstituted silane group, a substituted or unsubstituted alkylamine group, and a substituted or unsubstituted aryl amido group;
the general structural formula (II): 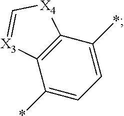
the general structural formula (II): 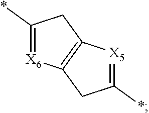
the general structural formula (IV): 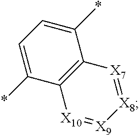
the general structural formula (V): 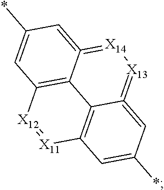
where X₃ represents N or CR; X₄ represents S, O or NR; X₅ and X₆ each independently represent S or O; X₇, X₈, X₉, X₁₀ all independently represent N or CR, and at least one of X₇, X₈, X₉, X₁₀ is N; X₁₁, X₁₂, X₁₃, X₁₄ each independently represent N or CR, and at least two of X₁₁, X₁₂, X₁₃, X₁₄ are N; * denotes a position to which the general structural formula (I) is connected.

13. The light emitting device of claim 12, wherein the L comprises any one of the following structures:

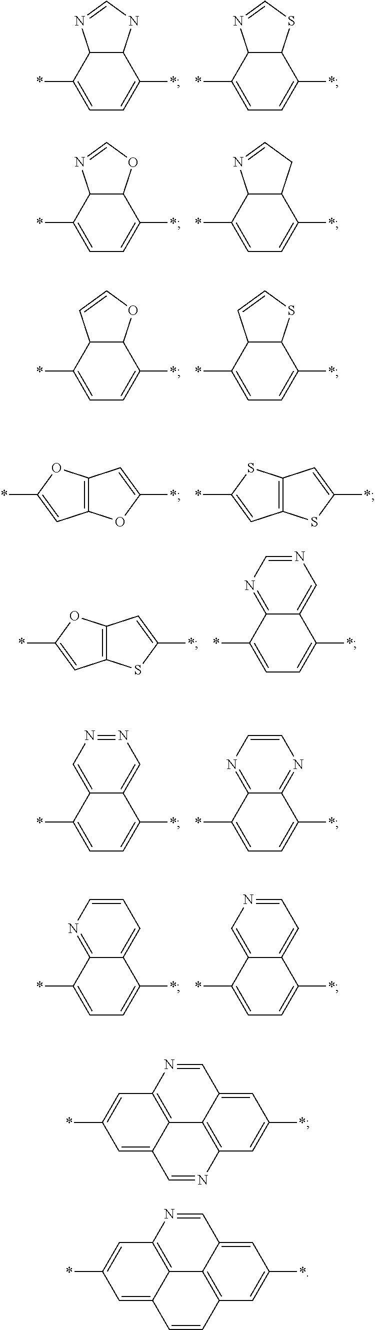

14. The light emitting device of claim 13, wherein the structure of the material of the first capping layer comprises any one of following structures:

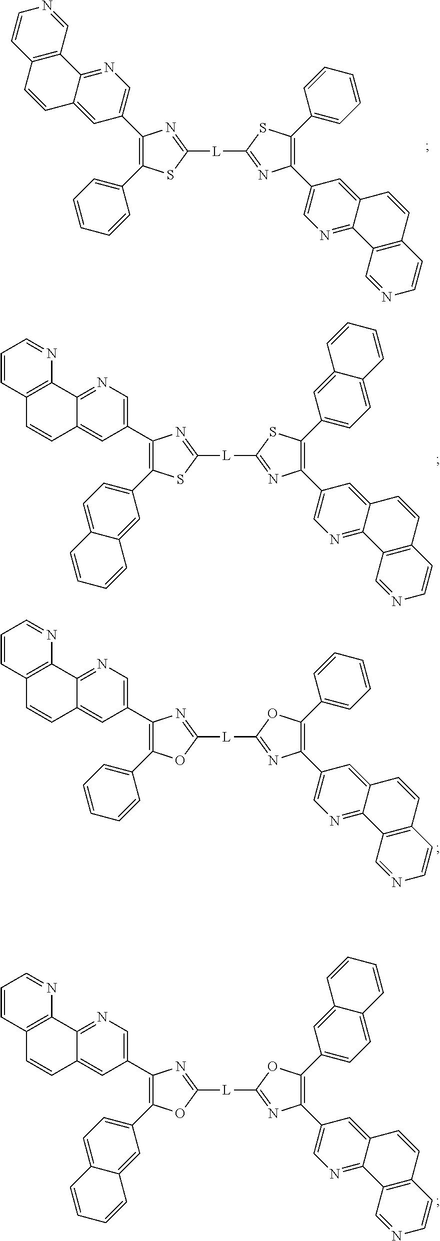

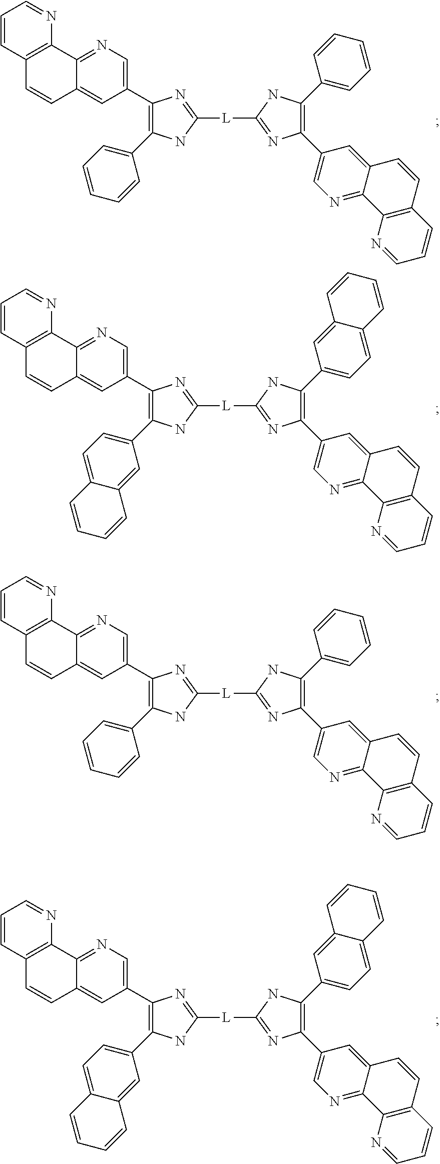

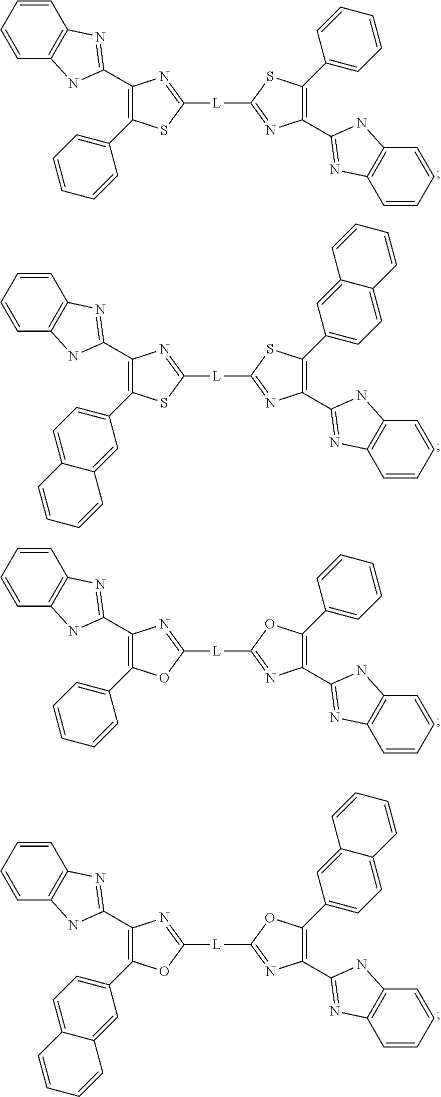

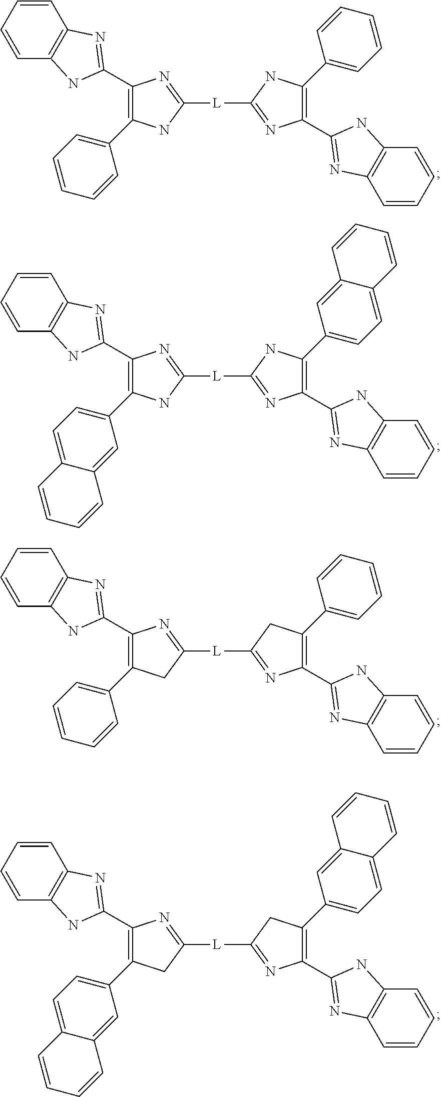

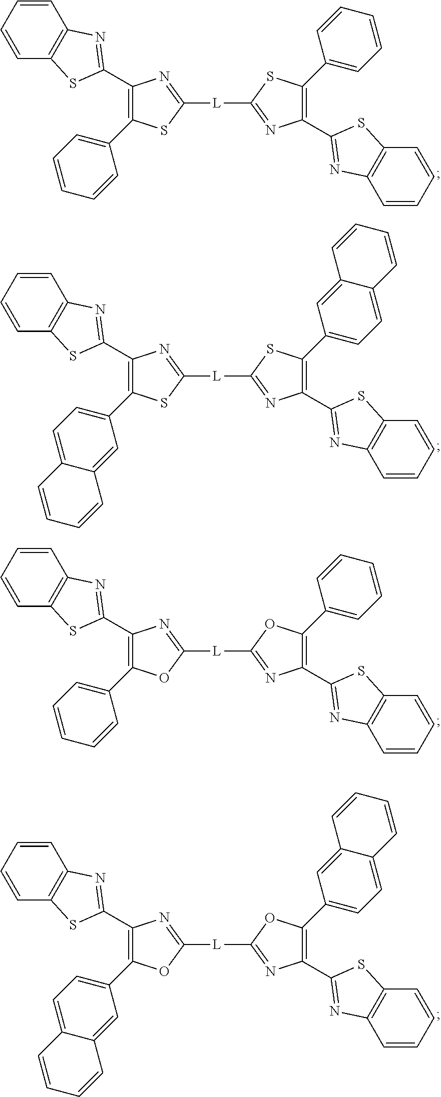

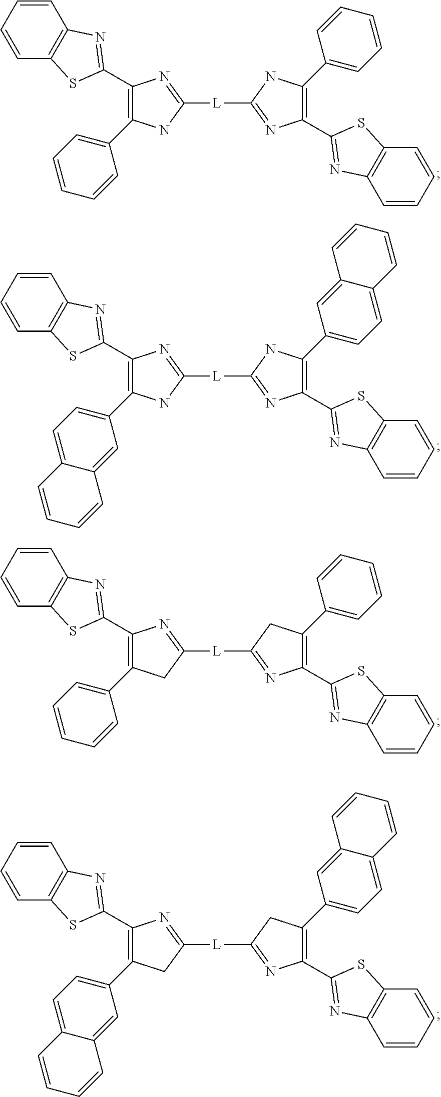

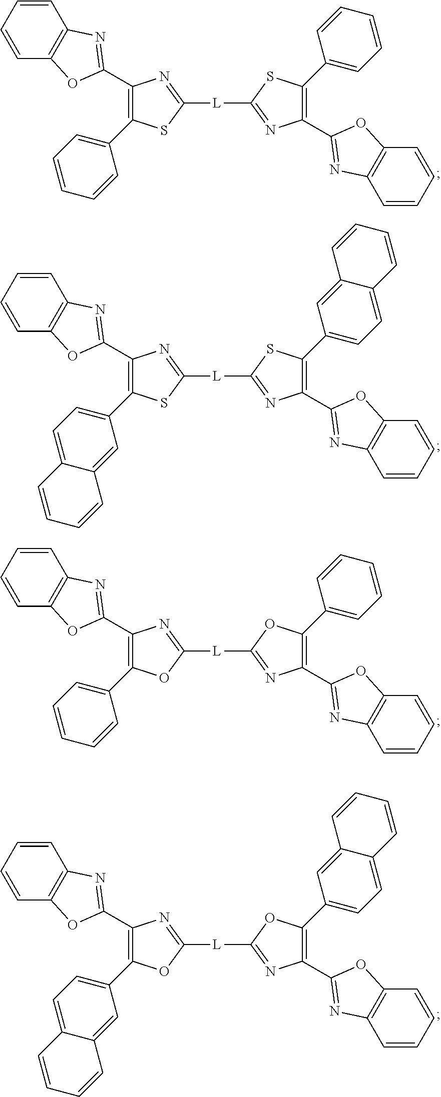

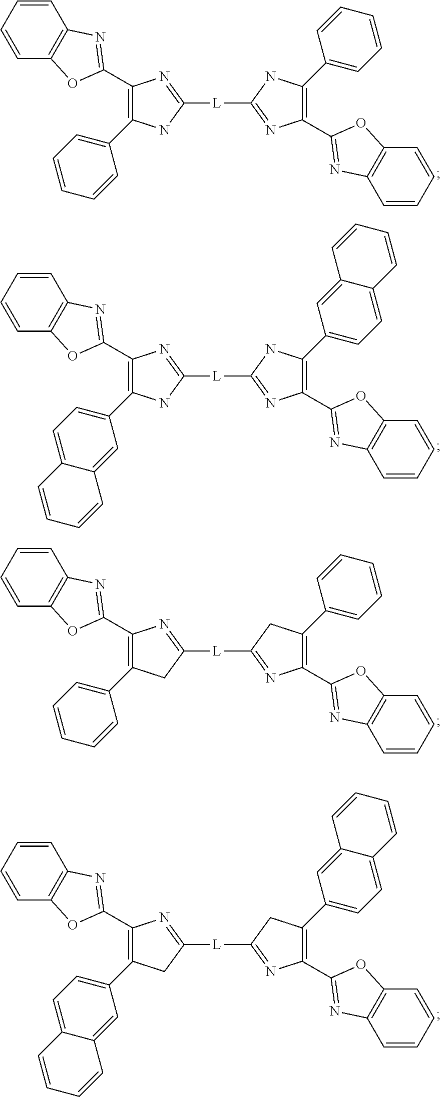

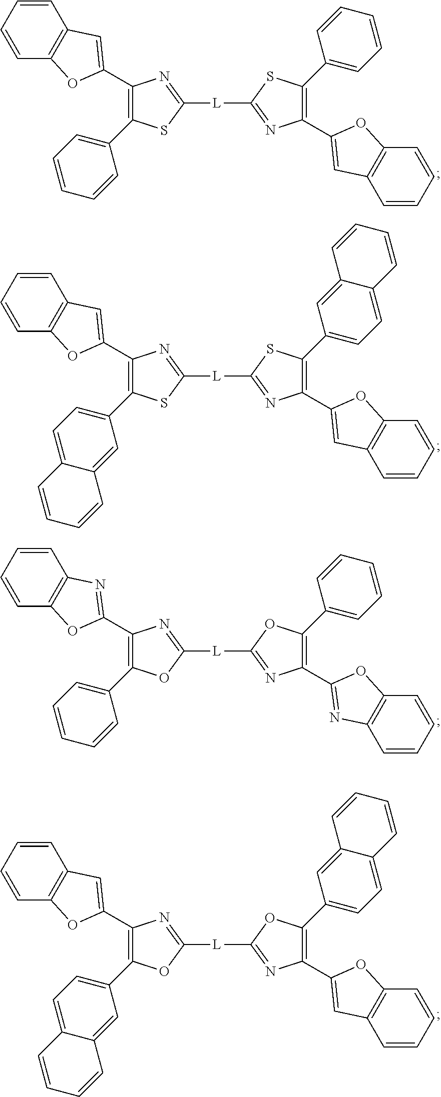

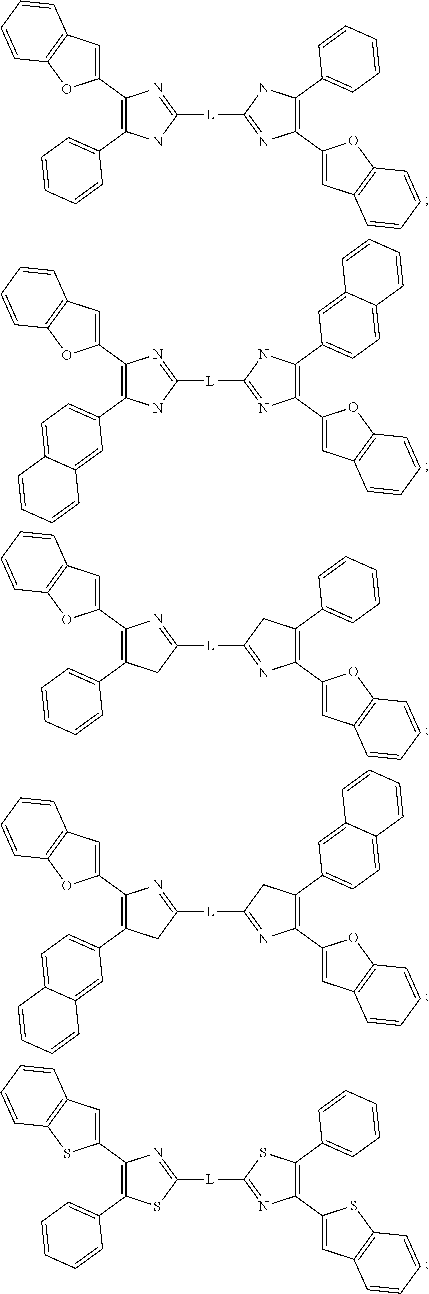

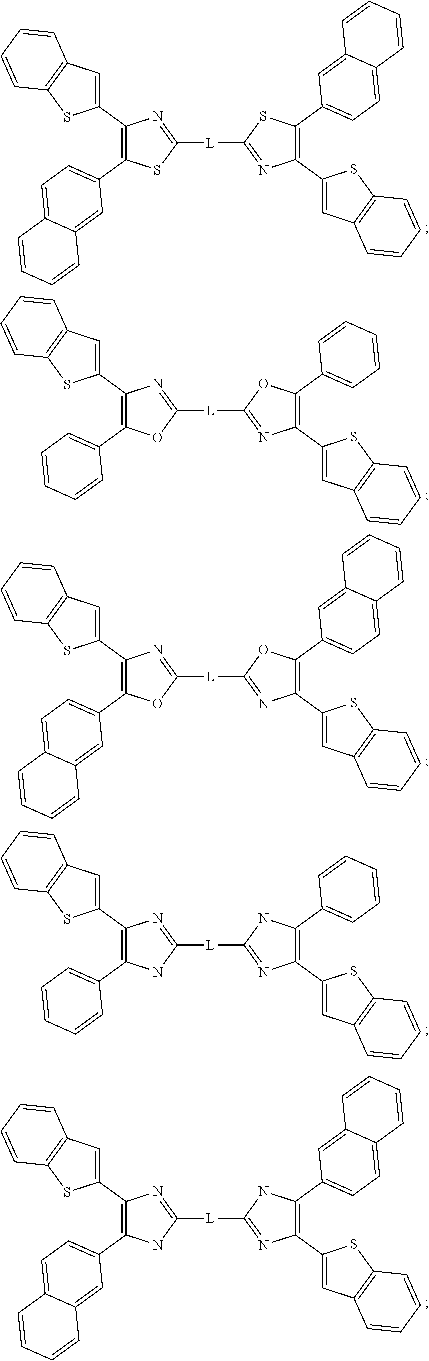

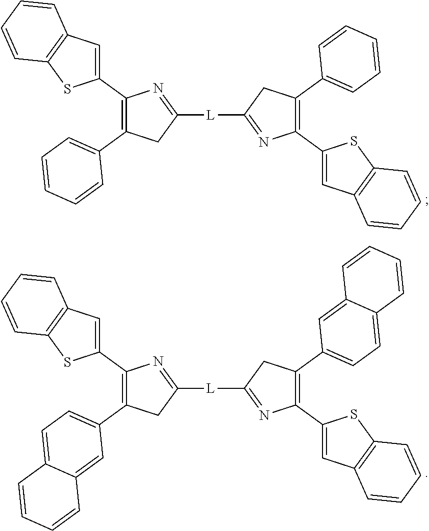

15. The light emitting device of claim 6, wherein a material of the second capping layer has the following general structural formula (VI):
the general structural formula (VI): 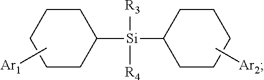
wherein, Ar₁ represents a general structural formula (VII) or (VIII), Ar₂ represents the general structural formula (VII) or (VIII);
the general structural formula (VII): 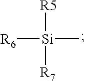
the general structural formula (VIII): 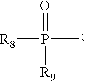
wherein, R₃, R₄, R₅, R₆, R₇, R₈, and R₉ each independently represent one of the following substances: a substituted or unsubstituted alkyl group, a substituted or unsubstituted cycloalkyl group, a substituted or unsubstituted heterocyclic group, a substituted or unsubstituted alkenyl group, a substituted or unsubstituted cycloalkenyl group, a substituted or unsubstituted alkynyl group, a substituted or unsubstituted alkoxy group, a substituted or unsubstituted alkylthio group, a substituted or unsubstituted aryl ether group, a substituted or unsubstituted aryl thioether group, a substituted or unsubstituted C6 to C60 aryl group, a substituted or unsubstituted C6 to C60 heteroaryl group, a substituted or unsubstituted carbonyl group, a substituted or unsubstituted oxycarbonyl group, a substituted or unsubstituted carbamoyl group, a substituted or unsubstituted silane group, a substituted or unsubstituted alkylamine group, and a substituted or unsubstituted aryl amido group.

16. The light emitting device of claim 15, wherein a part of hydrogen in any one of the following structures independently represented by R₃, R₄, R₅, R₆, R₇, R₈, and R₉ is substituted by deuterium: a substituted or unsubstituted alkyl group, a substituted or unsubstituted cycloalkyl group, a substituted or unsubstituted heterocyclic group, a substituted or unsubstituted alkenyl group, a substituted or unsubstituted cycloalkenyl group, a substituted or unsubstituted alkynyl group, a substituted or unsubstituted alkoxy group, a substituted or unsubstituted alkylthio group, a substituted or unsubstituted aryl ether group, a substituted or unsubstituted aryl thioether group, a substituted or unsubstituted C6 to C60 aryl group, a substituted or unsubstituted C6 to C60 heteroaryl group, a substituted or unsubstituted carbonyl group, a substituted or unsubstituted oxycarbonyl group, a substituted or unsubstituted carbamoyl group, a substituted or unsubstituted silane group, a substituted or unsubstituted alkylamine group, and a substituted or unsubstituted aryl amido group.

17. The light emitting device of claim 15, wherein the Ar₁ and the Ar₂ each comprise any one of the following structures: 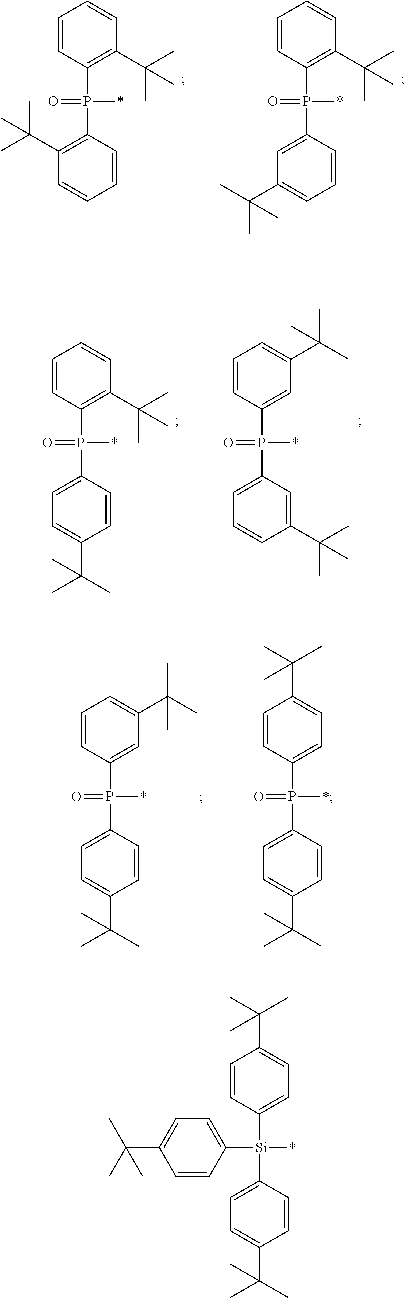
wherein, * denotes a position to which the general structural formula (VI) is connected.

18. The light emitting device of claim 17, wherein the structure of the material of the second capping layer comprises any one of the following structures:

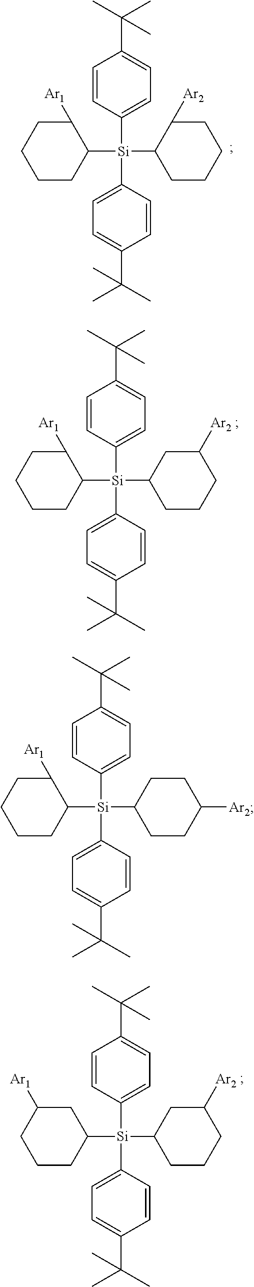

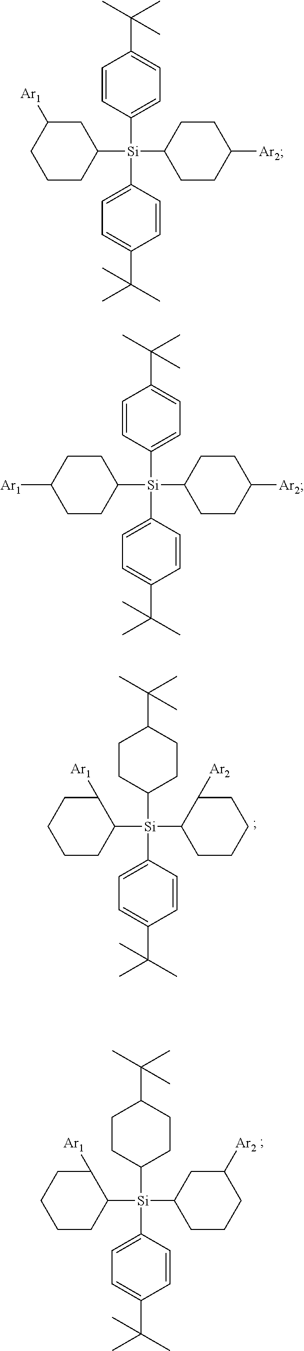

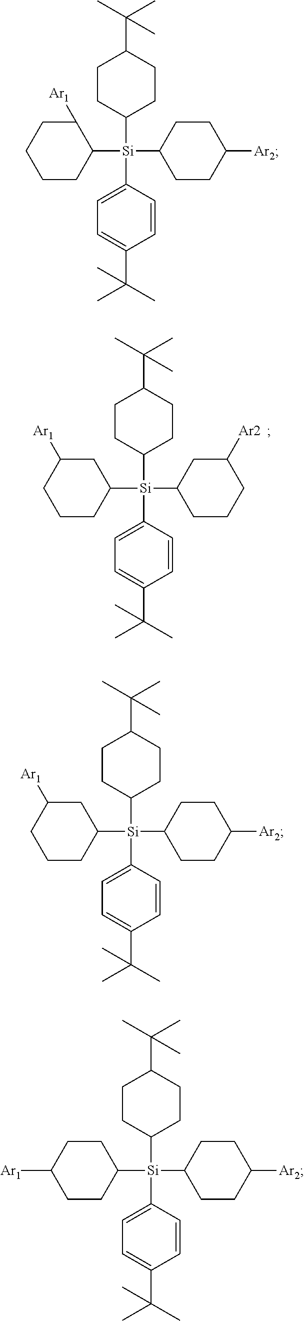

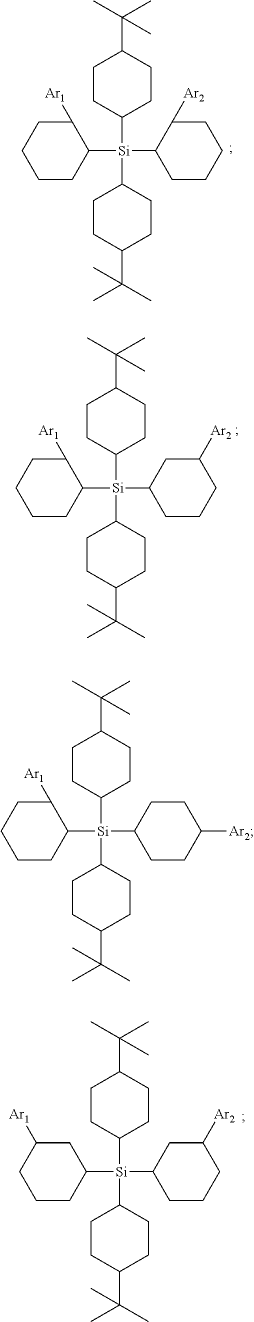

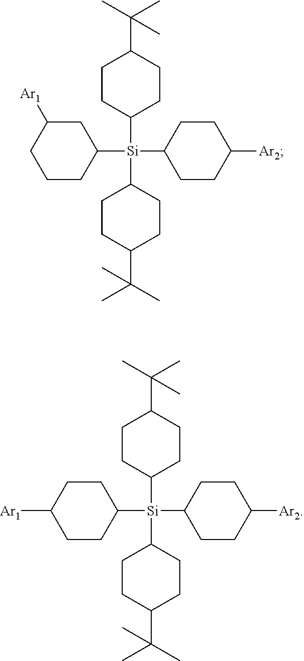

19. A display panel, comprising the light emitting device of claim 1.

20. The light emitting device of claim 7, wherein a material of the first capping layer has the following general structural formula (I): 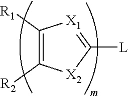
wherein, m is equal to 2; L represents any one of phenylene, biphenylene, naphthylene, a general structural formula (II), a general structural formula (III), a general structural formula (IV) and a general structural formula (V); X1 is N or CR, X2 is any one of S, O and NR, wherein R in CR, R in NR, R1 and R2 independently represent one of the following substances: hydrogen, deuterium, a substituted or unsubstituted alkyl group, a substituted or unsubstituted cycloalkyl group, a substituted or unsubstituted heterocyclic group, a substituted or unsubstituted alkenyl group, a substituted or unsubstituted cycloalkenyl group, a substituted or unsubstituted alkynyl group, a substituted or unsubstituted alkoxy group, a substituted or unsubstituted alkylthio group, a substituted or unsubstituted aryl ether group, a substituted or unsubstituted aryl thioether group, a substituted or unsubstituted C6 to C60 aryl group, a substituted or unsubstituted C6 to C60 heteroaryl group, a substituted or unsubstituted carbonyl group, a substituted or unsubstituted oxycarbonyl group, a substituted or unsubstituted carbamoyl group, a substituted or unsubstituted silane group, a substituted or unsubstituted alkylamine group, and a substituted or unsubstituted aryl amido group;
the general structural formula (II): 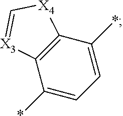
the general structural formula (III): 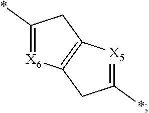
the general structural formula (IV): 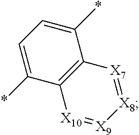
the general structural formula (V): 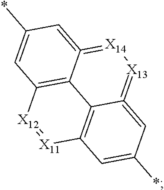
where X₃ represents N or CR; X₄ represents S, O or NR; X₅ and X₆ each independently represent S or O; X₇, X₈, X₉, X₁₀ all independently represent N or CR, and at least one of X₇, X₈, X₉, X₁₀ is N; X₁₁, X₁₂, X₁₃, X₁₄ each independently represent N or CR, and at least two of X₁₁, X₁₂, X₁₃, X₁₄ are N; * denotes a position to which the general structural formula (I) is connected.
